(19) United States
(12) Patent Application Publication
(10) Pub. No.: US 2007/0237189 A1
(43) Pub. Date: Oct. 11, 2007

(54) Method and apparatus for ONT ranging with improved noise immunity

(75) Inventors: Joseph D. Miguel, Petaluma, CA (US); E. Russel Smith, Sebastopol, CA (US)

Correspondence Address: HAMILTON, BROOK, SMITH & REYNOLDS, P.C., 530 VIRGINIA ROAD, P.O. BOX 9133, CONCORD, MA, 01742-9133, US

(73) Assignee: Tellabs Petaluma, Inc., Naperville, IL (US)

(21) Appl. No.: 11/514,421

(22) Filed: Sep. 1, 2006

Related U.S. Application Data
(63) Continuation-in-part of application No. 11/432,292, filed on May 10, 2006.
(60) Provisional application No. 60/789,357, filed on Apr. 5, 2006.

(51) Int. Cl. H01L 33/00

(52) U.S. Cl. 370/907; 257/96

(57) ABSTRACT

A method and corresponding apparatus for ranging an Optical Network Terminal (ONT) in a Passive Optical Network (PON) is provided. An example method may include: (i) transmitting a ranging request from an Optical Line Terminal (OLT) to an ONT in connection with a transport layer ranging window; (ii) monitoring for a ranging response from the ONT during at least one physical layer ranging window within the transport layer ranging window, the transport layer ranging window having a duration longer than the physical layer ranging window; and (iii) determining at least one metric associated with the ranging response for use in connection with upstream communications between the ONT and the OLT. The metric(s), used in connection with upstream communications, are accurately determined, and communications faults during normal operations are thus reduced.

### RELATED APPLICATIONS

This application is a Continuation-in-Part of U.S. application Ser. No. 11/432,292 filed on May 10, 2006 and Attorney Docket No. 2376.2079-002 entitled “Method and Apparatus for Diagnosing Problems on a Time Division Multiple Access (TDMA) Optical Distribution Network (ODN)”, filed on Aug. 31, 2006, both of which claim the benefit of U.S. Provisional Application No. 60/789,357, filed on Apr. 5, 2006. The entire teachings of the above applications are incorporated herein by reference.

### BACKGROUND OF THE INVENTION

A Passive Optical Network (PON) can contain multiple Optical Line Terminals (OLTs), each connected by a shared optical fiber to a respective Optical Distribution Network (ODN) with multiple Optical Network Terminals (ONTs) on individual optical fibers. ONTs can malfunction and interfere with communications between the ONTs and the OLT on a shared optical fiber. Such malfunctions are generally the result of power outages or typical communication systems errors or failures. Other disruptions in communications can be caused by optical fibers being cut, such as by a backhoe. If ONTs are malfunctioning for any other reason, identifying the issue requires a technician to inspect each ONT, possibly causing costly interruptions to service.

### SUMMARY OF THE INVENTION

A method for ranging an Optical Network Terminal (ONT) in a Passive Optical Network (PON) is provided. The method according to an example embodiment of the invention includes: (i) transmitting a ranging request from an Optical Line Terminal (OLT) to an ONT in connection with a transport layer ranging window; (ii) monitoring for a ranging response from the ONT during at least one physical layer ranging window within the transport layer ranging window, the transport layer ranging window having a duration longer than the physical layer ranging window; and (iii) determining at least one metric associated with the ranging response for use in connection with upstream communications between the ONT and the OLT. The metric(s), used in connection with upstream communications, are accurately determined, and communications faults during normal operations are thus reduced.

### BRIEF DESCRIPTION OF THE DRAWINGS

The foregoing will be apparent from the following more particular description of example embodiments of the invention, as illustrated in the accompanying drawings in which like reference characters refer to the same parts throughout the different views. The drawings are not necessarily to scale, emphasis instead being placed upon illustrating the principles of the invention.

FIG. 1 is a network diagram of an exemplary passive optical network (PON);

FIG. 2 is a power level diagram illustrating power levels associated with an input signal and a no-input signal in accordance with example embodiments of the invention;

FIG. 3A is block diagram illustrating layer 2 communications established between an optical line terminal (OLT) and optical network terminals (ONTs) in accordance with example embodiments of the invention;

FIG. 3B is a network block diagram illustrating measuring a no-input signal power level on an upstream communications path prior to establishing layer 2 communications between an optical line terminal (OLT) and an optical network terminal (ONT) in accordance with example embodiments of the invention;

FIG. 3C is a network block diagram illustrating measuring a no-input signal power level on an upstream communications path after establishing layer 2 communications between an optical line terminal (OLT) and optical network terminals (ONTs) in accordance with example embodiments of the invention;

FIGS. 4A-4C are upstream communications frames illustrating example embodiments of measurements of a no-input signal power level on an upstream communications path being measured during a time there are no upstream communications;

FIG. 5 is a power level diagram illustrating an extinction ratio and no-input extinction ratio in accordance with example embodiments of the invention;

FIG. 6A is a power level diagram illustrating an integrated no-input signal power level ramping over time;

FIG. 6B is a timing diagram illustrating an integrated no-input signal power level ramping over a ranging window;

FIG. 7A is a block diagram of an exemplary optical line terminal (OLT);

FIG. 7B is a block diagram of an exemplary processor supporting example embodiments of the invention;

FIG. 8A is a flow diagram of an exemplary process performed in accordance with an example embodiment of the invention;

FIG. 8B is a flow diagram of an exemplary process performed in accordance with an example embodiment of the invention;

FIG. 9 is a message diagram illustrating a procedure of ranging an ONT;

FIGS. 10A and 10B are message diagrams illustrating communications from communicating ONTs halted, and a ranging request and a ranging response exchanged, during a transport layer ranging window in accordance with an example embodiment of the invention;

FIG. 11 is a diagram illustrating lengths of a transport layer ranging window, physical layer ranging window, and ranging response in accordance with an example embodiment of the invention;

FIGS. 12A and 12B are a timing diagram illustrating an integrated no-input signal power level ramping over a physical layer ranging window in accordance with example embodiments of the invention;

FIG. 13 is a series of timing diagrams illustrating dynamically adjusting a physical layer ranging window in an iterative manner in accordance with an example embodiment of the invention;

FIG. 14 is a series of timing diagrams illustrating shifting a physical layer ranging window within a transport layer ranging window in accordance with an example embodiment of the invention;

FIGS. 15A-C are a series of timing diagrams illustrating shifting a physical layer ranging window incrementally across the transport layer ranging window in accordance with an example embodiment of the invention;

FIG. 16 is a timing diagram illustrating shifting a physical layer ranging window by an amount expected to result in receiving a ranging response in full in accordance with an example embodiment of the invention;

FIG. 17 is a timing diagram illustrating lengthening the duration of the physical layer ranging window in accordance with an example embodiment of the invention;

FIG. 18 is a diagram illustrating monitoring for ranging response during a series of physical layer ranging windows in accordance with an example of embodiment of the invention;

FIGS. 19A and 19B are diagrams illustrating shifting a series of physical layer ranging windows by an amount expected to result in receiving a ranging response in full in accordance with an example embodiment of the invention;

FIG. 20 is a diagram illustrating reducing a physical layer ranging window if a measured no-input signal power level exceeds a threshold in accordance with an example embodiment of the invention;

FIG. 21 is a block diagram of an exemplary optical line terminal (OLT) supporting example embodiments of the invention;

FIG. 22 is a block diagram of an exemplary monitor unit supporting examples embodiments of the invention;

FIG. 23 is a flow diagram of an exemplary process performed in accordance with an example embodiment of the invention;

FIG. 24 is a flow diagram of an exemplary process performed in accordance with an example embodiment of the invention; and

FIG. 25 is a flow diagram of another exemplary process performed in accordance with an example embodiment of the invention.

### DETAILED DESCRIPTION OF THE INVENTION

A description of example embodiments of the invention follows.

An optical network terminal (ONT) can malfunction in such a way that it sends a continuous stream of light (e.g., low level, such as less than 10 dBm) up to a shared fiber of an optical distribution network (ODN). This can adversely affect communications between ONTs on the ODN and an optical line terminal (OLT). Using existing error detection techniques, such as those described in various passive optical network (PON) protocols, this type of ONT malfunction may not be detected. Even if it is detected (e.g., resulting from system failure), the ONT malfunction (i.e., output of continuous light at a low level) may not be identified, and field service engineers may spend a great deal of time inspecting a receiver in the OLT, fiber optic cables between the ONTs and OLT, and any relays or junctions between the ONTs and OLT. Moreover, the amount of continuously outputted light which can cause communications errors has been found to be very low. So, unless field service engineers are sensitive to the source of the communications errors, hours of lost network services can result.

Detection of an ONT sending a low level continuous stream of light up to a shared fiber of an ODN may be done several ways. One method may involve individually disconnecting ONTs from the ODN to determine if there is a single ONT or multiple ONTs causing the problem. With this method, however, the problem may not be corrected in a timely fashion. Additionally, this method requires considerable customer downtime. In another method, the OLT may be disconnected from the ODN, and the ODN may be examined with additional test equipment. Besides requiring additional test equipment, this method does not identify the ONT which is outputting too much light on a continuous basis.

Accordingly, what is needed is a method or corresponding apparatus for diagnosing problems on an ODN which detects, prior to establishing layer 2 communications, a malfunctioning ONT by looking for an inappropriate presence of a modulated or unmodulated upstream optical signal when no signal should be present on the upstream communications path. Furthermore, after establishing layer 2 communications with any number of ONTs, a malfunctioning ONT may be detected by looking for an inappropriate presence of an unmodulated or very low level modulated upstream optical signal when no signal should be present on the upstream communications path.

As used herein, a modulated upstream optical signal is a signal which conveys information (i.e., communicates upstream communications data) and is interchangeably referred to herein as an “input signal”). The input signal may be either a “zero-bit input signal” (i.e., communicates a zero-bit) or a “one-bit input signal,” i.e., communicates a one-bit. In contrast, an unmodulated upstream optical signal is a signal which does not convey information (i.e., communicates no upstream communications data) and is interchangeably referred to herein as a “no-input signal.”

Further, power levels associated with a zero-bit input signal or a one-bit input signal are referred to herein as a “zero-bit input signal power level” or a “one-bit input signal power level,” respectively. Additionally, a power level associated with a no-input signal is referred to herein as a “no-input signal power level.”

In a PON system, multiple ONTs transmit data to an OLT using a common optical wavelength and fiber optic media. Field experience has demonstrated that a malfunctioning ONT can send an optical signal up to the OLT at inappropriate times, resulting in the OLT not being able to communicate with any of the ONTs on the ODN. A typical PON protocol provides some functionality for detecting this problem, but is limited only to inappropriate modulated signals. Consequently, the following ONT malfunctions are not being detected.

An example ONT malfunction not being detected involves an ONT sending a continuous upstream signal (modulated or unmodulated) up the fiber prior to attempting to establish communications with an OLT on an ODN. Another example ONT malfunction occurs when an ONT sends an unmodulated light signal up the fiber at an inappropriate time while attempting to establish communications or after having established communications with an OLT on an ODN. Consequently, an ability to detect the aforementioned ONT example malfunctions may depend on an ability to detect an unmodulated light signal.

While an OLT must be able to detect the presence of a modulated signal (or an input signal) in order to function as a node in a communications path, the ability to detect an unmodulated signal (or a no-input signal), however, is not required for operation. In accordance with example embodiments of the invention, the ability to detect an unmodulated upstream signal may improve the ability of the OLT to detect error conditions in upstream communications between ONTs and the OLT, as discussed hereinafter.

As such, in part, a difference between detecting a modulated versus an unmodulated upstream signal is that an optical receiver (or transceiver) does not have the ability to detect an unmodulated signal. In some cases, the optical receiver may not be able to detect or communicate the presence of an unmodulated upstream signal.

In other cases, even though the presence of an unmodulated signal may indicate a system problem, the presence of an unmodulated signal may not actually result in a problem in upstream communications between ONTs and an OLT. Sometimes the presence of an unmodulated upstream signal is removed by signal conditioning circuitry on the optical receiver (or transceiver). The unmodulated upstream signal adds; a “DC” offset to a modulated upstream signal. The “DC” offset may be subsequently removed from the modulated upstream signal without corrupting it. Current experience, however, indicates that the effect of an unmodulated upstream signal on a modulated upstream signal varies from optical receiver to optical receiver.

A method for diagnosing problems on a time division multiple access (TDMA) optical distribution network (ODN) is provided. A method according to an example embodiment of the invention includes: (i) measuring a no-input signal power level on a communications path configured to carry upstream communications between multiple optical network terminals (ONTs) and an optical line terminal (OLT) in a passive optical network (PON) at a time no upstream communications are on the communications path from the ONTs to the OLT; (ii) comparing the measured no-input signal power level to a threshold; and (iii) generating a notification in an event the threshold is exceeded.

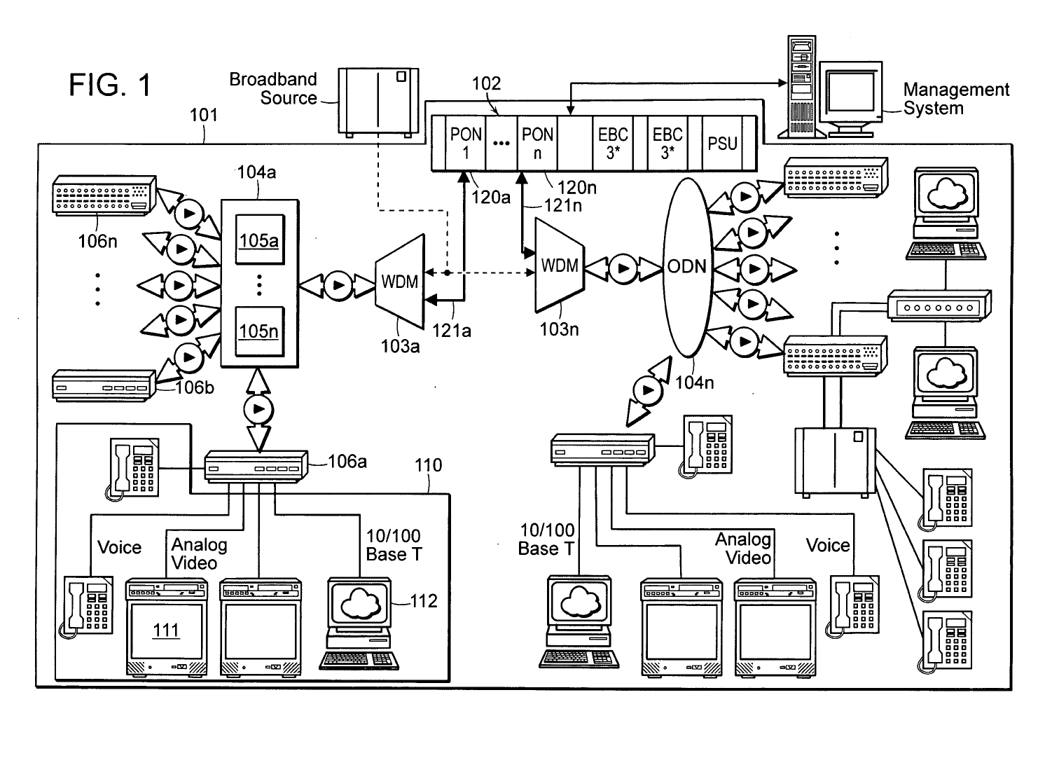

FIG. 1 is a network diagram of an exemplary passive optical network (PON) 101. The PON 101 includes an optical line terminal (OLT) 102, wavelength division multiplexers 103a-n, optical distribution network (ODN) devices 104a-n, ODN device splitters (e.g., 105a-n associated with ODN device 104a), optical network terminals (ONTs) (e.g., 106-n corresponding to ODN device splitters 105a-n), and customer premises equipment (e.g., 110). The OLT 102 includes PON cards 120a-n, each of which provides an optical feed (121a-n) to ODN devices 104a-n. Optical feed 121a, for example, is distributed through corresponding ODN device 104a by separate ODN device splitters 105a-n to respective ONTs 106a-n in order to provide communications to and from customer premises equipment 110.

The PON 101 may be deployed for fiber-to-the-business (FTTB), fiber-to-the-curb (FTTC), and fiber-to-the-home (FTTH) applications. The optical feeds 121a-n in PON 101 may operate at bandwidths such as 155 Mb/sec, 622 Mb/sec, 1.25 Gb/sec, and 2.5 Gb/sec or any other desired bandwidth implementations. The PON 101 may incorporate asynchronous transfer mode (ATM) communications, broadband services such as Ethernet access and video distribution, Ethernet point-to-multipoint topologies, and native communications of data and time division multiplex (TDM) formats. Customer premises equipment (e.g., 110) which can receive and provide communications in the PON 101 may include standard telephones (e.g., Public Switched Telephone Network (PSTN)), Internet Protocol telephones, Ethernet units, video devices (e.g., 111), computer terminals (e.g., 112), digital subscriber line connections, cable modems, wireless access, as well as any other conventional device.

A PON 101 includes one or more different types of ONTs (e.g., 106a-n). Each ONT 106a-n, for example, communicates with an ODN device 104a through associated ODN device splitters 105a-n. Each ODN device 104a-n in turn communicates with an associated PON card 120a-n through respective wavelength division multiplexers 103a-n. Wavelength division multiplexers 103a-n are optional components which are used when video services are provided. Communications between the ODN devices 104a-n and the OLT 102 occur over a downstream wavelength and an upstream wavelength. The downstream communications from the OLT 102 to the ODN devices 104a-n may be provided at 622 megabytes per second, which is shared across all ONTs connected to the ODN devices 104a-n. The upstream communications from the ODN devices 104a-n to the PON cards 120a-n may be provided at 155 megabytes per second, which is shared among all ONTs connected to ODN devices 104a-n.

Error conditions in upstream communications between an optical line terminal (OLT) and optical network terminals (ONTs) often result in layer 2 communication errors, for example, errors in ranging or normalization parameters. One such error condition in upstream communications is the presence of an unmodulated signal (or a no-input signal) on an upstream communications path. An example solution to this problem may include detecting the presence of an unmodulated signal on the upstream communications path, identifying whether the detected unmodulated signal leads to a layer 2 communications error, and communicating the error condition so that it may be corrected. An unmodulated signal on the upstream communications path may be detected by measuring a power level associated with the unmodulated signal. For the sake of readability, the power level associated with the unmodulated signal is referred to herein as a “no-input signal power level” and is used throughout this disclosure.

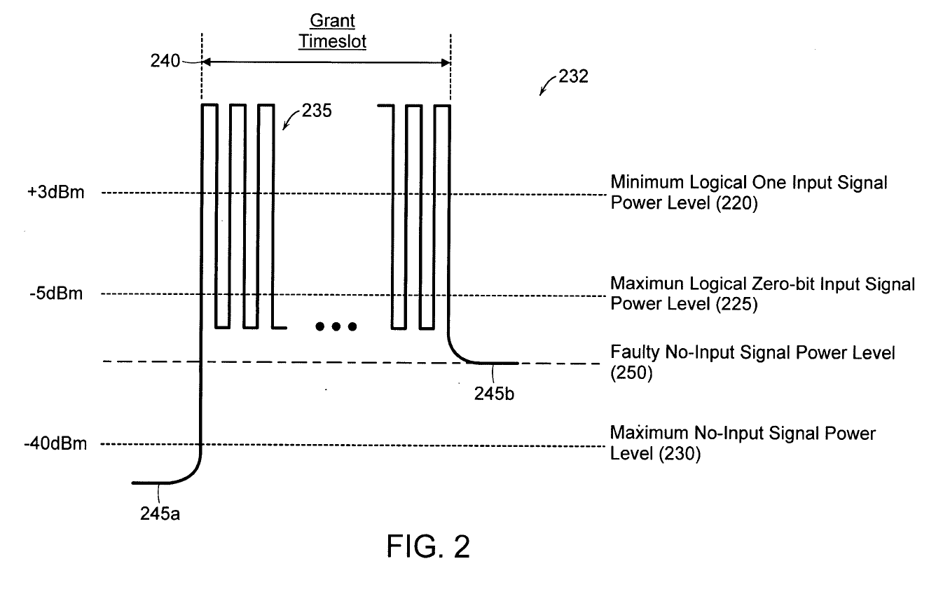

FIG. 2 illustrates three power levels: a minimum logical one input signal power level 220, a maximum logical zero input signal power level 225, and a maximum no-input signal power level 230. The terms logical one and logical zero are interchangeably referred to herein as a one-bit and a zero-bit.

In general, when the power level of an input signal is above the minimum logical one input signal power level 220, the input signal is designated as a logical one input signal. When the power level of an input signal is below the maximum logical zero input signal power level 225, the input signal is designated as a logical zero input signal. When the power level of an input is below the minimum logical one input signal power level 220 but above the maximum logical zero input signal power level 225, the input signal is indeterminate, i.e., the input signal is neither a logical one input signal nor is the input signal a logical zero input signal.

In this way, by modulating or otherwise changing the power level of an input signal, the input signal can either convey a logical one input signal or a logical zero input signal. Moreover, by modulating the power level of an input signal, the input signal conveys information. Accordingly, upstream communications between an ONT and OLT on an upstream communications pathway is accomplished by modulating the power level of an input signal to an optical transmitter generating optical signals.

In contrast, when the power level of a signal is not modulated, the signal conveys no information. This is the case when there are no upstream communications between an ONT and an OLT on an upstream communications pathway. In this disclosure, the term no-input signal is used to describe a signal whose power level is not modulated. Furthermore, the terms unmodulated signal and no-input signal are used interchangeably throughout this disclosure.

When the power level of a no-input signal is below the maximum no-input signal power level 230, a no-input signal is said to be valid or non-faulty. More specifically, a no-input signal with a power level less than the maximum no-input signal power level 230 does not or is less likely to cause an error condition. On the other hand, when the power level of a no-input signal is above the maximum no-input signal power level 230, the no-input signal is said to be invalid or faulty. In contrast to a no-input signal with a power level less than the maximum no-input signal power level 230, a no-input signal with a power level greater than the maximum no-input signal power level 230 does or is more likely to cause an error condition (described later in greater detail).

Still referring to FIG. 2, consider the following illustrative example. The minimum logical one input signal power level 220 is +3 dBm (decibel-milliwatt), the maximum logical zero input signal power level 225 is −5 dBm, and the maximum no-input signal power level 230 is −40 dBm.

An input signal 232 with a series of power levels 235 is received during a grant timeslot 240. During the grant timeslot 240, the input signal 232 has power levels which at times are greater than +3 dBm and at times are less than −5 dBm. Thus, the series of power levels 235 in the input signal 232 designates a series of logical ones and logical zeros. Before the grant timeslot 240, a first no-input signal portion 245a of the input signal 232 has a power level less than −40 dBm. As such, the first no-input signal portion 245a of the input signal 232 is not faulty, i.e., validly conveys no information.

In contrast, after the grant timeslot 240, a second no-input signal portion 245b of the input signal 232 has a power level greater than −40 dBm, e.g., a “faulty no-input signal level” 250. In this case, the second no-input signal portion 245b of the input signal 232 is faulty, i.e., invalidly conveys no information. Discussed later in greater detail, a no-input signal having a power level, such as the faulty no-input signal power level 250, may lead to problems in upstream communications, e.g., errors in ranging and normalization parameters.

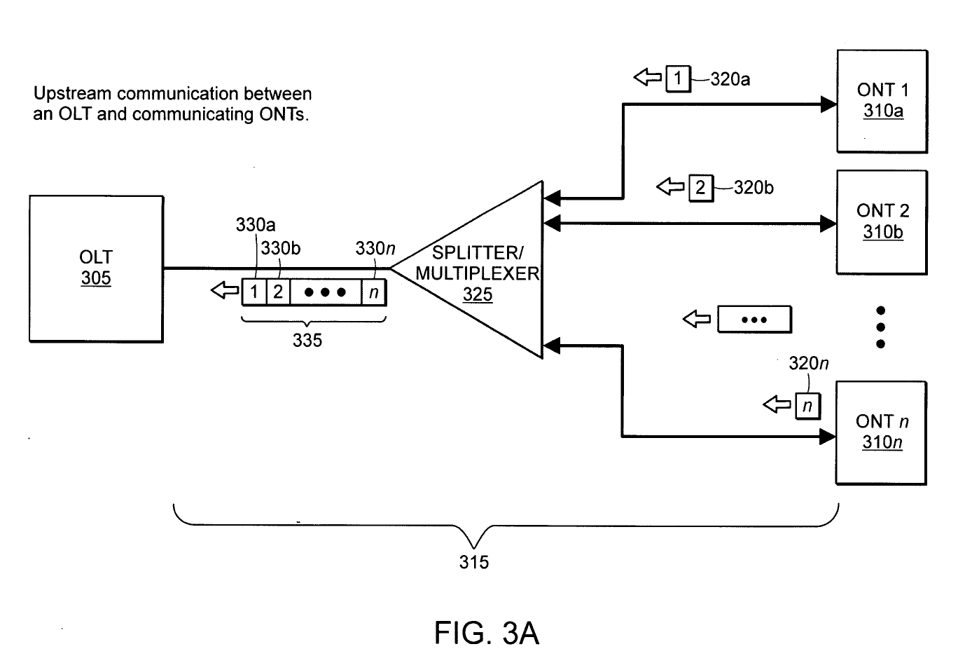

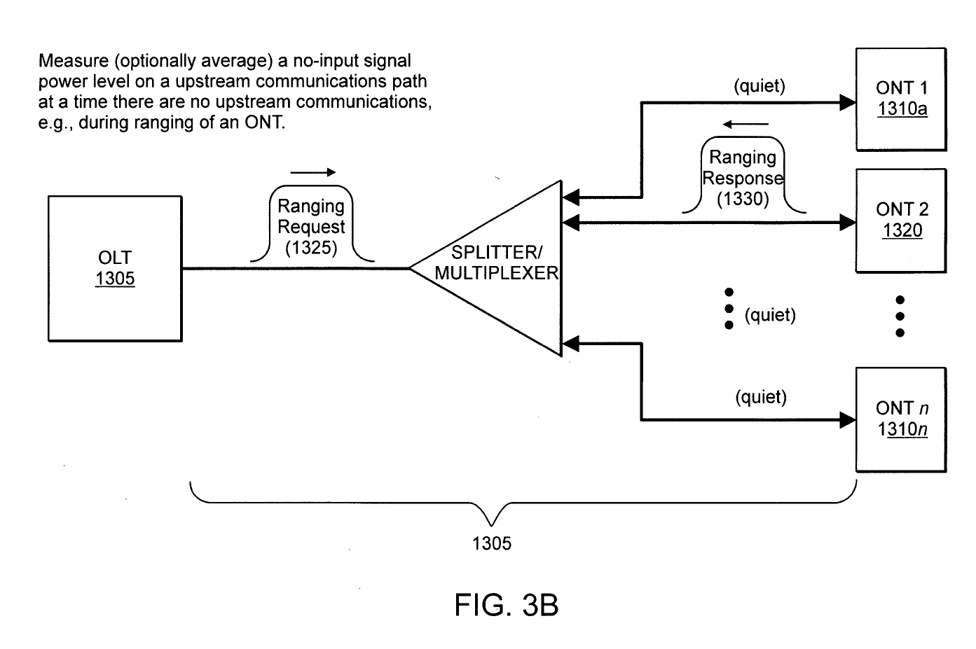

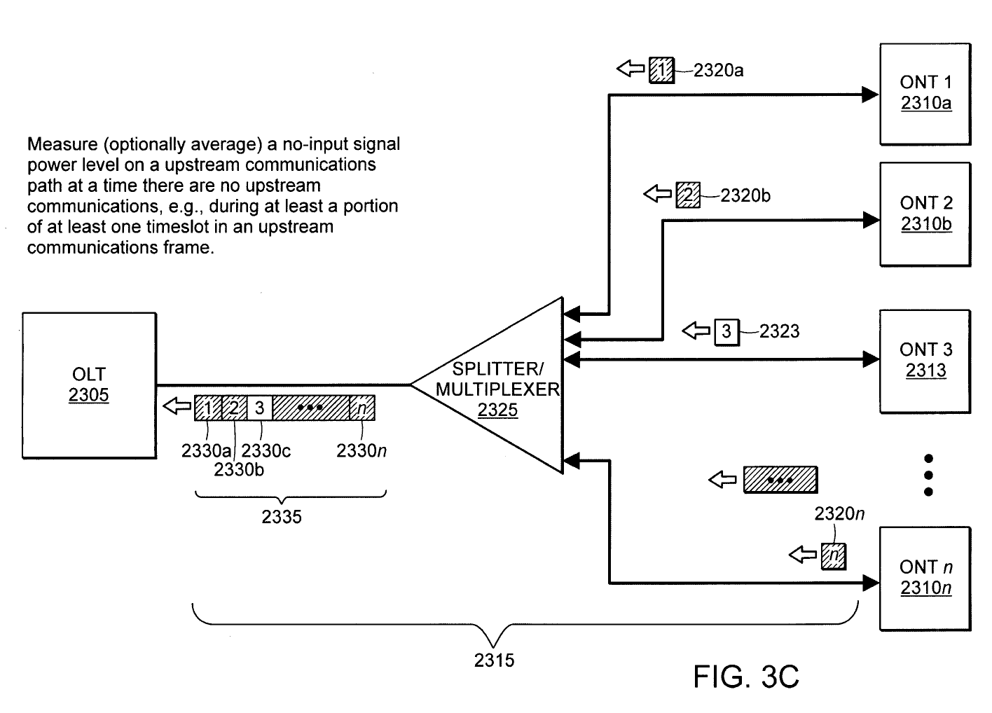

FIG. 3A illustrates upstream communications between an OLT 305 and communicating ONTs 310a-n over an upstream communications path 315. Upstream communications begins when the communicating ONTs 310a-n transmit upstream communications data 320a-n on the upstream communications path 315. Upstream communications data 320a-n are then combined on the upstream communications path 315 by a splitter/multiplexer 325. Upstream communications data 320a-n are transmitted by the communicating ONTs 310a-n at respective predefined times and in the case of a time division multiplexing (TDM) communications protocol, placed into individual timeslots 330a-n of an upstream communications frame 335.

The OLT 305, via the upstream communications path 315, receives the upstream communications frame 335. The OLT 305 may then demultiplex (i.e., separate) the upstream communications frame 335 into individual timeslots 330a-n. As a result, the OLT 305 receives respective upstream communications data 320a-n from each communicating ONT 310a-n.

FIG. 3B is a network block diagram illustrating how an OLT 1305 may measure a power level of a no-input signal (or a no-input signal power level) on an upstream communications path 1315 at a time there are no upstream communications between the OLT 1305 and communicating ONTs 1310a-n. The no-input signal power level on the upstream communications path 1315 may be measured at a time the OLT 1305 is ranging an ONT 1320 or at another time there are no upstream communications on the upstream communications path 1315, e.g., when the OLT 1305 is immediately rebooted and before any ONTs are ranged.

In an example embodiment, the OLT 1305 may instruct all communicating ONTs 1310a-n to halt upstream communications in order to range the ONT 1320. With upstream communications from the communicating ONTs 1310a-n halted, the no-input signal power level on the upstream communications path 1315 should be small, (e.g., a power level below the maximum no-input signal power level 230 of FIG. 2) or have no value, Typically, once halted, any power present on the upstream communications path 1315 is caused by, for example, very low level leakage of optical transmitters (e.g., laser diodes) in transmitter units of the communicating ONTs 1310a-n or due to typical optical noise developed or imparted onto the upstream communications path 1315.

The OLT 1305 may send the ONT 1320 a ranging request 1325. The ONT 1320, in turn, may respond with a ranging response 1330. During the ranging, the no-input signal power level on the upstream communications path 1315 is measured during period(s) the ranging response 1330 is not on the upstream communications path 1315. As such, the no-input signal power level is not increased by a signal representing the ranging response 1330. If the no-input signal power level is greater than, for example, the maximum no-input signal power level 230 of FIG. 2, the ONT 1320 is faulty.

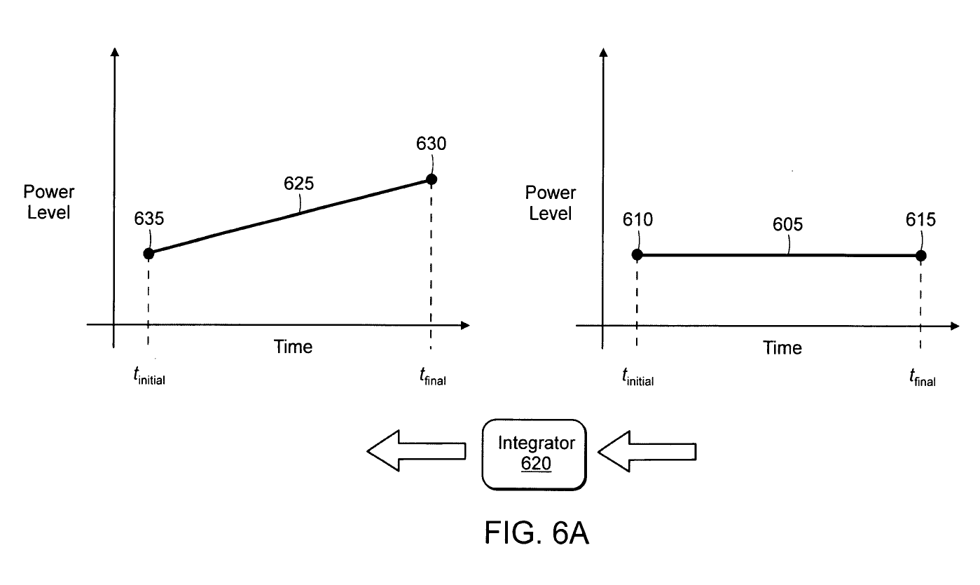

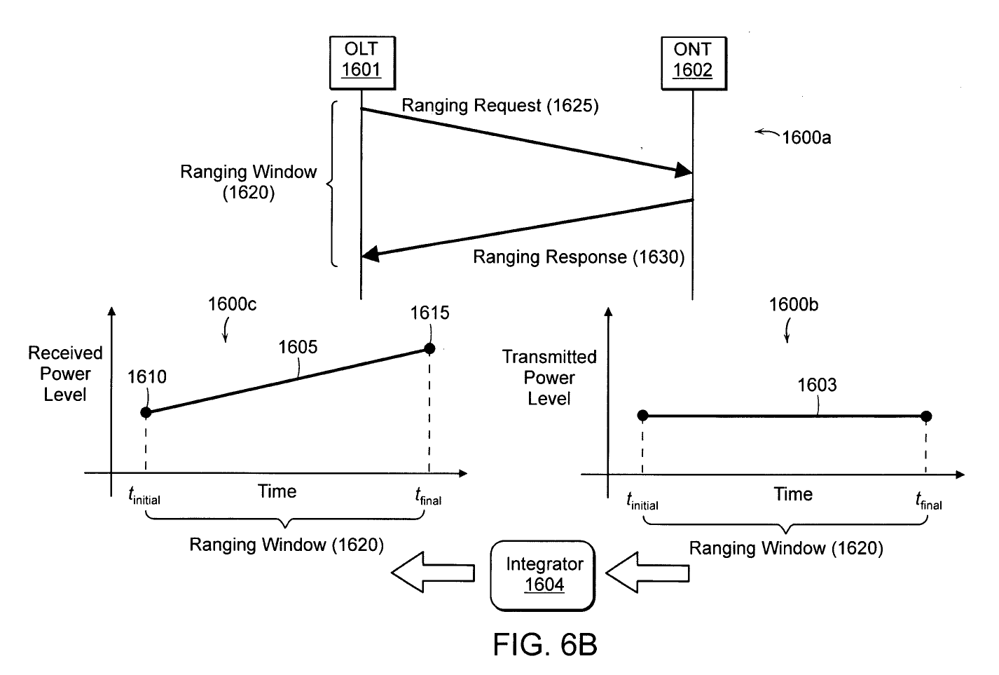

The ranging exchange between the OLT 1305 and the ONT 1320 may occur over a period of time known as a ranging window (not shown, but discussed below in reference to FIG. 6B). The measured no-input signal power level on the upstream communications path 1315 may be averaged over an un-allocated grant window (not shown). In addition to measuring a no-input signal power level during the un-allocated grant window, a no-input signal power level may also be measured before any ONTs have been ranged, e.g., when the OLT 1305 is rebooted.

FIG. 3C is a network block diagram in which upstream communications between an OLT 2305 and communicating ONTs 2310a-n are carried over an upstream communications path 2315. In addition to the communicating ONTs 2310a-n, there is a non-communicating ONT 2313. Upstream communications begin with the communicating ONTs 2310a-n sending upstream communications data 2320a-n via the upstream communications path 2315. The non-communicating ONT 2313 may have no-data to send. Consequently, rather than sending upstream communications data 2320, nothing is sent, denoted by a “no-data” indicator 2323. For purposes of explaining aspects of the invention, the “no-data” indicator 2323 indicates a timeslot portion that is neither filled with an “idle” signal or a substantive upstream communications signal. The upstream communications data 2320a-n and the no-data 2323 are then combined by splitter/multiplexer 2325. The upstream communications data 2320a-n and the no-data 2323 are transmitted in their respective timeslots 2330a-n of upstream communications frame 2335.

The OLT 2305, via the upstream communications path 2315, receives the upstream communications frame 2335. The OLT 2305 then demultiplexes (or separates) the upstream communications frame 2335 into individual timeslots 2330a-n. Consequently, the OLT 2305 receives from each communicating ONT 2310a-n upstream communications data 2320a-n. The OLT 2305 also “receives” the no-data 2323 from the non-communicating ONT 2313.

While the OLT 2305 is “receiving” the no-data 2323 in the timeslot 2330c of the upstream communications frame 2335, a no-input signal power level on the upstream communications path 2315 may be measured. In another example embodiment, a no-input signal power level may be measured on an upstream communications path at a time there are no upstream communications for least a portion of at least one timeslot in an upstream communications frame.

In contrast to the previous example, the non-communicating ONT 2313 may send an “idle” signal (not shown) or a message indicating there is no data to be sent (not shown). In this situation a no-input signal power level on the upstream communications path 2315 cannot be measured.

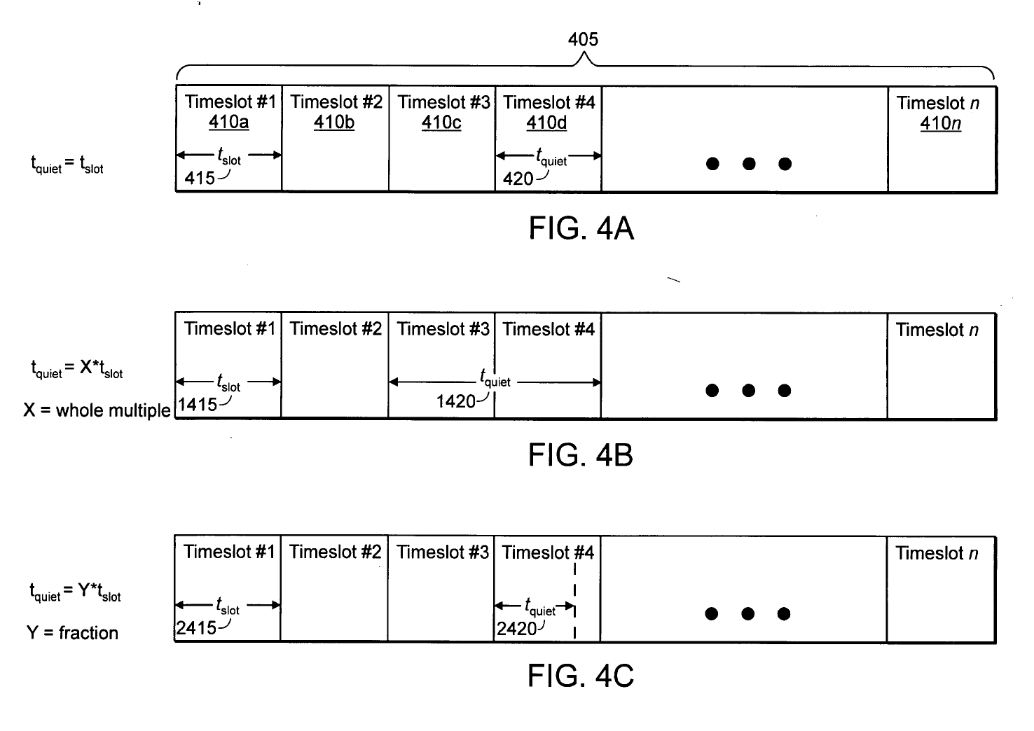

FIG. 4A is an example embodiment of the invention in which an upstream communications frame 405 has n number of timeslots 410a-n. Each timeslot 410a-n grants (or allocates) a time for upstream communications 415 (referred to herein as tₛₗₒₜ). It is during the tₛₗₒₜ 415 that upstream communications data is communicated from an ONT to an OLT. In the upstream communications frame 405, an “unused” timeslot (i.e., a timeslot without upstream communications data) defines a time for no-upstream communications 420 (referred to herein as t_{quiet}). It is during the t_{quiet} 420 that a no-input signal power level on an upstream communications path may be measured. An unused timeslot such as t_{quiet} 420 may occur in networks with more timeslots than ONTs.

In this example embodiment, the t_{quiet} 420 is equal to the tₛₗₒₜ 415. As such, if the tₛₗₒₜ is 1.2 μs, for example, the no-input signal power level on an upstream communications path may be measured for as long as 1.2 μs.

FIG. 4B is another example embodiment illustrating a time for no-upstream communications 1420 (referred to herein as t_{quiet}) optionally equal to some whole multiple of a time for upstream communications 1415 (referred to herein as tₛₗₒₜ). For example, if the tₛₗₒₜ 1415 is 1.2 μs, the t_{quiet} 1420 may be two, three, etc., times the length of the tₛₗₒₜ 1415. Accordingly, a no-input signal power level on an upstream communications path is measured for 2.4 μs, 3.6 μs, etc., where the longer time typically results in improved accuracy of the power level measurement.

FIG. 4C is yet another example embodiment in which a time for no-upstream communications 2420 (referred to herein as t_{quiet}) is equal to some fraction of a time for upstream communications 2415 (referred to herein as tₛₗₒₜ). For example, if the tₛₗₒₜ 2415 is 1.2 μs, the t_{quiet} 2420 may be a quarter, one and half, etc. times the length of the tₛₗₒₜ 2415. Accordingly, a no-input signal power level on an upstream communications path may be measured for 0.3 μs, 1.8 μs, etc.

In still yet other example embodiment, a no-input signal power level on an upstream communications path may be measured during a time there are no upstream communications (e.g., t_{quiet} 1420 or when no communications frames are communicated in an upstream direction) and then averaged, resulting in an averaged measurement, to increase noise immunity. By measuring a no-input signal power level on an upstream communications path at a time there are no upstream communications, an error condition of very small optical power levels can be detected. Having detected such an error condition, a determination may be made as to whether the error condition may lead to layer 2 communications errors, such as errors in the ranging or normalization parameters.

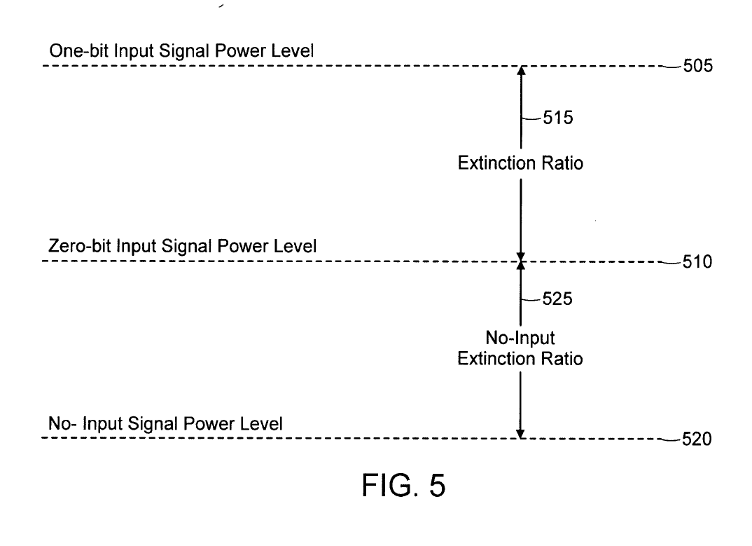

FIG. 5 illustrates a ratio between a one-bit input signal power level 505 and a zero-bit input signal power level 510. This ratio is referred to herein as an extinction ratio 515. The extinction ratio 515 is a measure of a contrast (or a distinction) between power levels of input signals designating a one-bit input signal and a zero-bit input signal. For example, if the extinction ratio 515 is large, the distinction between a one-bit input signal power level and a zero-bit input signal power level is also large. Because the distinction between the power levels is large, an optical receiver has an easier task in detecting an input signal as either a one-bit input signal or a zero-bit input signal. In contrast, if the extinction ratio 515 is small, the distinction between a one-bit input signal power level and a zero-bit input signal power level is also small, and an optical receiver has a more difficult task in detecting an input signal as either a one-bit input signal or a zero-bit input signal.

A similar ratio may be said to exist between the zero-bit input signal power level 510 and a no-input signal power level 520. This ratio is referred to herein as a no-input extinction ratio 525. Like the extinction ratio 515, the no-input extinction ratio 525 is a measure of a contrast (or a distinction) between a power level of an input signal designating a zero-bit input signal and a power level of a no-input signal. For example, if the no-input extinction ratio 525 is large, the distinction between a zero-bit input signal power level and a no-input signal power level is also large. Because the distinction between power levels is large, an optical receiver has an easier task in detecting a zero-bit input signal or a no-input signal. In contrast, if the no-input extinction ratio 525 is small, the distinction a zero-bit input signal power level and a no-input signal power level is also small, and an optical receiver has a more difficult task in detecting a zero-bit input signal or a no-input signal.

Difficulties in distinguishing between a no-input signal and a zero-bit input signal may also lead to difficulties in distinguishing between a one-bit input signal and a zero-bit input signal. As a consequence, there may be an increase in the number of bit errors which occur during normal communications. As such, it desirable to have a no-input extinction ratio which is sufficiently large enough to prevent such bit errors.

FIG. 6A is a power level diagram illustrating a no-input signal 605 which has a power level at time tᵢₙᵢₜᵢₐₗ 610 equal to a power level at time t_{final} 615. The power level of the no-input signal 605 (i.e., no-input signal power level) may be integrated (or added) by an integrator 620 (or other electronics) in an optical power receiver (or transceiver) to produce an integrated no-input signal power level 625. The integrator 620 integrates from time tᵢₙᵢₜᵢₐₗ to time t_{final}, resulting in an integrated no-input signal power level at t_{final} 630 being greater than an integrated no-input signal power level at tᵢₙᵢₜᵢₐₗ 635, as is expected. The longer the period of integration time, the higher the integrated no-input signal power level 625 is ramped (or increased). Consequently, over time, a no-input extinction ratio (see FIG. 5) becomes smaller, and it is more difficult to distinguish a no-input signal from a zero-bit input signal. Further, the higher the integrated no-input signal power level at tᵢₙᵢₜᵢₐₗ 635, the more significant the resulting integrated no-input signal power level 625 becomes over time and the smaller a no-input extinction ratio becomes over the same time.

FIG. 6B is a diagram illustrating how a transmitted optical power level from a faulty ONT affects measurement during ranging of an ONT by an OLT. A message diagram 1600a illustrates an exchange of ranging messages between an OLT 1601 and an ONT 1602 during a ranging window 1620. A transmitted power level versus time plot 1600b illustrates the ONT 1602 transmitting a no-input signal power level 1603 during the ranging window 1620. A received power level versus time plot 1600c illustrates the OLT 1601 receiving the no-input signal power level 1603, which has been integrated by an integrator 1604 in a receiver (not shown) of the OLT 1604, as an integrated no-input signal power level 1605.

The transmitted power level versus time plot 1600b indicates that the no-input signal power level 1603 may be constant during the ranging window 1620, where the constant level may be a normal low level (e.g., −40 dBm) or a faulty high level (e.g., between −30 dBm and −25 dBm, or higher). The integrated no-input signal power level 1605 ramps up from an integrated no-input signal power level at time tᵢₙᵢₜᵢₐₗ 1610 to an integrated no-input signal power level at time t_{final} 1615, over the ranging window 1620.

In operation, while the no-input signal power level 1603 is being integrated over the ranging window 1620, the OLT 1601 sends a ranging request 1625 to the ONT 1602. The ONT 1602, in turn, responds with a ranging response 1630. The OLT 1601, having sent the ranging request 1625, receives the ranging response 1630 from the ONT 1602 during the ranging window 1620 or it reports a ranging error.

Typically, the receiver of the OLT 1601 is reset between adjacent upstream timeslots to accommodate power levels which vary from ONT to ONT. During ONT ranging, however, an upstream timeslot is effectively enlarged to accommodate variability in supported fiber lengths, i.e., more than one timeslot is used for the ranging window 1620. For example, the ONT 1602 may be located up to 20 kilometers away from the OLT 1601. To accommodate this distance, the duration of the ranging window 1620 is set sufficiently long enough to allow the ONT 1602 located 20 kilometers away from the OLT 1601 to receive the ranging request 1625 and the OLT 1601 to receive the ranging response 1630.

When the duration of the ranging window 1620 is set for a long period of time, the receiver of the OLT 1601 is not reset during this period of time. As a result, no-input signal power levels from non-transmitting ONTs on the ODN have more time to be integrated by the receiver of the OLT 1601, thus increasing the integrated no-input signal power level 1605. This increase has a negative impact on a signal condition circuitry in the receiver of the OLT 1601. In other words, the longer the duration of the ranging window 1620, the greater the effects of a small no-input extinction ratio (see FIG. 5). Consequently, it may be difficult to distinguish between a zero-bit input signal power level and a one-bit input signal power level possibly leading to upstream communications problem(s).

In one embodiment of the present invention, prior to ranging an ONT, an OLT instructs communicating ONTs to halt upstream communications. Despite upstream communications being halted, there still may be a no-input signal from one or more halted ONTs causing a “faulty no-input signal power level” (see FIG. 2). Consequently, the faulty no-input signal power level may be integrated, causing the integrated no-input signal power level 1605 to increase further.

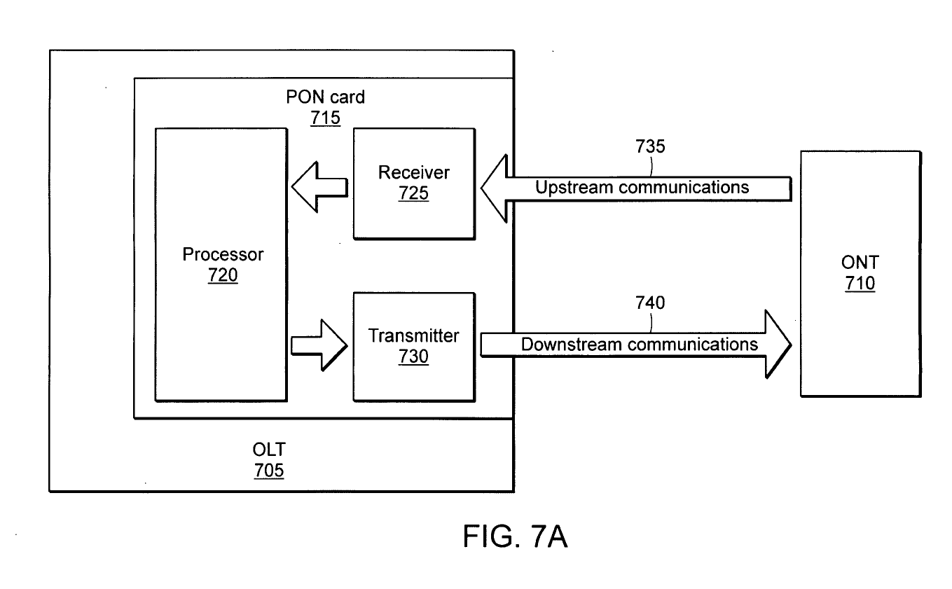

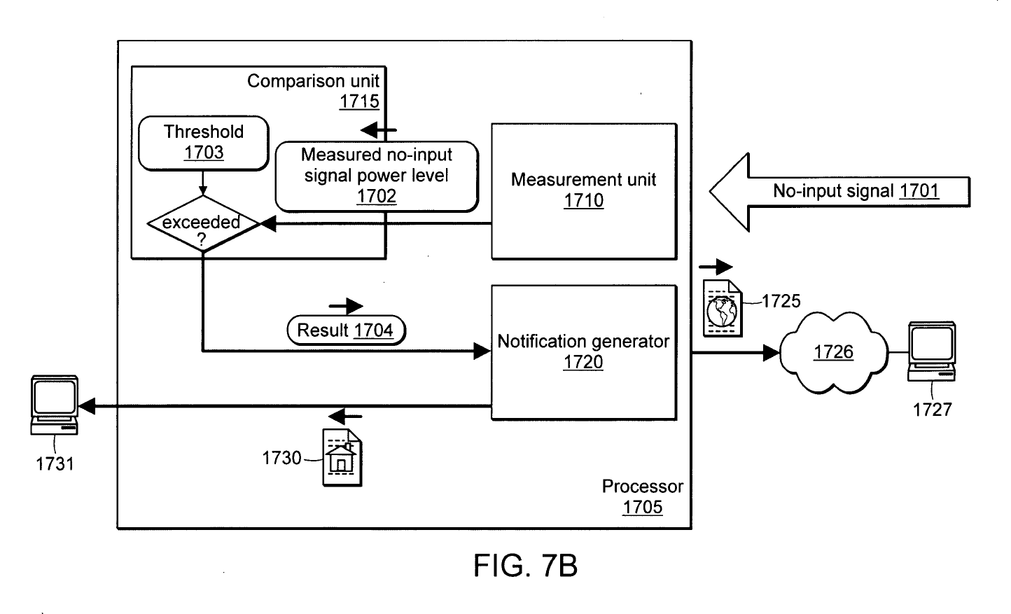

FIG. 7A is a block diagram of an exemplary OLT 705 in communication with an ONT 710. In this particular example, the OLT 705 has a PON card 715. The PON card 715 includes a processor 720 communicatively coupled to a receiver 725 and a transmitter 730. Alternatively, the receiver 725 and the transmitter 730 may be integrated into a single transceiver (not shown). In the direction toward from the OLT 705, the receiver 725 (or transceiver) receives upstream communications 735. The processor 720 subsequently processes the upstream communications 735. In the opposite direction toward the ONT 710, the processor 720 sends, via the transmitter 730 (or transceiver), downstream communications 740.

FIG. 7B is a block diagram which illustrates an exemplary processor 1705, supporting example embodiments of the invention, operating in a PON card of an OLT. The processor 1705 may include a measurement unit 1710, a comparison unit 1715, and a notification generator 1720. Alternatively, some or all of the aforementioned components may not be co-located with the processor 1705, but may be remotely located connected via a communications bus (not shown).

In operation of this example embodiment, the measurement unit 1710 may measure a power level of a no-input signal 1701 on an upstream communications path. The measurement unit 1710 may include an integrator, such as the integrator 620 of FIG. 6A, or other electronics to measure the power level of the no-input signal 1701. A measured no-input signal power level 1702 may be compared against a threshold value 1703 by the comparison unit 1715. A result 1704 from the comparison unit 1715 is communicated to the notification generator 1720. The notification generator 1720 may generate a notification if the communicated result 1704 indicates the measured no-input signal power level 1702 exceeds the threshold 1703. Keeping the integrated no-input signal power levels of FIGS. 6A and 6B in mind, it should be understood that the comparison unit 1715 may compare a maximum, an average (at multiple times or over a length of time), or a portion of the measured no-input signal power level 1702 against the threshold 1703.

The threshold 1703 against which the measured no-input signal power level 1702 is compared may be determined or defined in multiple ways. For example, the threshold 1703 may be set to a value equal to a “tolerable no-input signal power level” multiplied by a number of ONTs in communication with the OLT. Field experience may indicate a no-input signal power level of −20 dBm to −30 dBm per ONT often leads to problems in upstream communications. Based on such experience, the tolerable no-input signal power level may be −40 dBm. Therefore, in an example network having thirty-two ONTs communicating with an OLT, the threshold may be calculated as −40 dBm multiplied by thirty-two. Additionally, losses between the ONTs and the OLT (i.e., ODN losses) may be accounted for in calculating the threshold. In another example embodiment, the tolerable no-input signal power level may be less than a zero-bit input signal power level specified for the ONTs. One skilled in the art will readily appreciate that the value of the tolerable no-input signal power level may not be fixed (i.e., set to the same level for all communications networks, but rather may depend on characteristics of a communications network.

The threshold 1703 may alternatively represent a maximum power level corresponding to a fault associated with upstream communications in a noncommunicating state. In another example embodiment, the threshold 1703 may be less than a sum of a zero-bit input signal power level of each ONT offset by respective losses between the ONTs and the OLT. It should be understood that the threshold 1703 may be predetermined based on a configuration of a passive optical network or determined based on some other metric.

Continuing to refer to FIG. 7B, the notification generator 1720 may generate a remote notification 1725 which is sent over a network 1726 to, for example, a remote user or remote management system 1727. Alternatively, the notification generator 1720 may generate a local notification 1730, which is presented locally to, for example, a local user or local management system 1731. It should be understood that the remote notifications 1725 may be any form of signal (e.g., analog, digital, packet, and so forth), data values, including in header or load portions of packets, and so forth. The local notification 1730 may also be any form of signal or may be audio or visual alarms to alert an operator at a console at the OLT that an error as described herein had occurred.

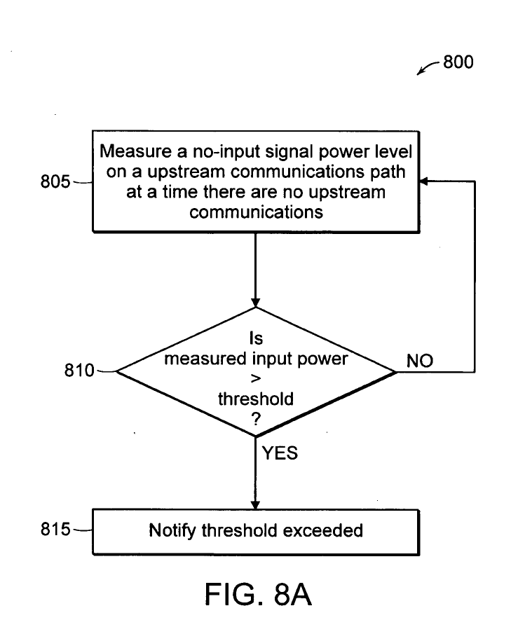

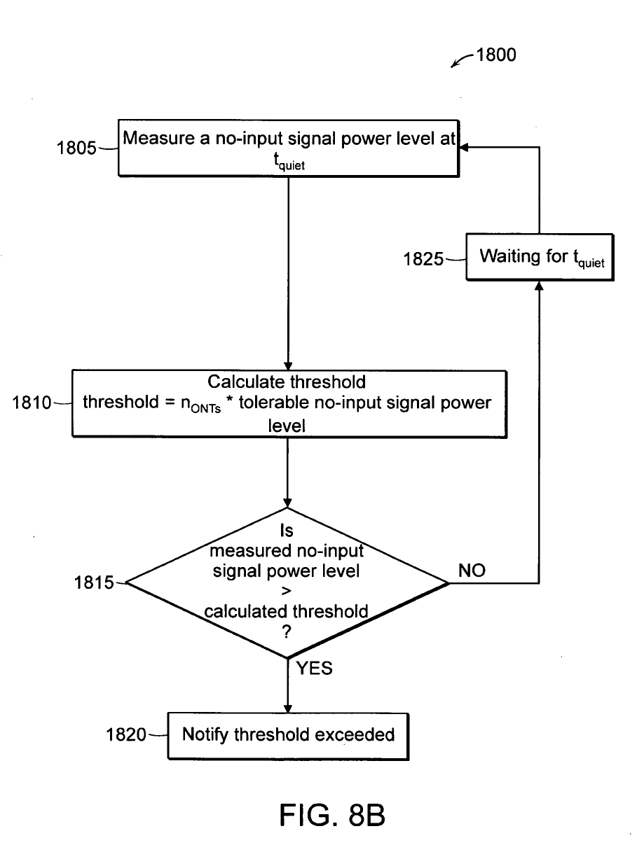

FIG. 8A is a flow diagram illustrating an exemplary process 800 for diagnosing a problem on an ODN. A no-input signal power level on an upstream communications path may be measured (805) at a time no upstream communications are on the upstream communications path. The measured no-input signal power level may be compared (810) against a threshold. If the measured no-input signal power level on the upstream communications path is greater than the threshold, a notification may be issued (815) to alert an operator (or management system) that the threshold is exceeded. If, however, the measured no-input signal power level on the upstream communications path is not greater than the threshold, the process 800 may return to begin measuring (805) the no-input signal power level.

FIG. 8B is a flow diagram illustrating a process 1800 for diagnosing a problem on an ODN in accordance with an example embodiment of the invention. A no-input signal power level on an upstream communications path may be measured (1805) at a time no upstream communications are on the upstream communications path. In this example embodiment, the no-input signal power level is measured during a time for no upstream communications (t_{quiet}). In reference to FIGS. 4A-4C, the time for no upstream communications (t_{quiet}) may be equal to a time for upstream communications (tₛₗₒₜ). Alternatively, the time for no upstream communications (t_{quiet}) may be equal to a whole multiple or fraction of the time for upstream communications (tₛₗₒₜ).

Next, a threshold may be calculated (1810). In this example embodiment, the threshold is equal to a number of ONTs on the ODN multiplied by a tolerable no-input signal power level. The tolerable no-input signal power level may be estimated based on system modeling, equal to a value measured at a time known not be experiencing an error condition (e.g., initial system set-up), and so forth.

The measured no-input signal power level on the upstream communications path may be compared (1815) against the calculated threshold. If the measured no-input signal power level is greater than the calculated threshold, a notification may be issued (1820) that the calculated threshold is exceeded. If, however, the measured no-input signal power level on the upstream communications path is less than the calculated threshold, the process 1800 may wait (1825) for the time for no upstream communications (t_{quiet}) to reoccur. After waiting, the process 1800 may once again measure (1805) the no-input signal power level on the upstream communications path.

As previously described, diagnosing a passive optical network (PON) for problems may involve detecting, prior to establishing layer 2 communications, a malfunctioning Optical Network Terminal (ONT). A malfunctioning ONT may be detected by looking for an inappropriate presence of a modulated or unmodulated upstream optical signal when no signal should be present on the upstream communications path. The inappropriate presence of such signals may cause a power level associated with these signals (i.e., a no-input signal power level) to be integrated over time by an integrator in a receiver to produce an integrated no-input signal power level. As expected, over time the integrated no-input signal power level increases, causing a no-input extinction ratio to become smaller. Consequently, it becomes more difficult to distinguish a no-input signal from a zero-bit input signal, possibly leading to bit errors. In less severe cases, a higher than expected no-input signal power level may result in erroneous settings of parameters used in connection with upstream communications.

The effect of integrating a no-input signal power level is particularly significant when ranging an ONT. While ranging, an integrator (or other electronics) in an Optical Line Terminal (OLT) receiver (or transceiver) may integrate (or otherwise calculate) a no-input signal power level for an extended period of time. Accordingly, what is needed is a method or a corresponding apparatus for ranging an ONT in a passive optical network in a manner minimizing the aforementioned effects caused by the inappropriate presence of an unmodulated or modulated optical signal on the upstream communications path or other times when such presence causes adverse effects, directly indirectly on upstream communications. It should be understood that alternative embodiments may be employed in situations involving downstream communications.

ITU specification 693.1, Section 8.4.2.5.2, describes shortening a ranging window when the location of an ONT to be ranged is known With a priori knowledge, a ranging window may be shortened to correspond to a known distance between the OLT and the ONT. According to shortening the ranging window done in prior art systems by reducing a transport layer ranging window (layer 2) and a physical layer ranging window (layer 1) in equal amounts.

By shortening a ranging window, disruption to communicating ONTs is minimized. Since communicating ONTs are disabled from communicating in the upstream direction during ranging, the shorter the ranging window, the shorter the amount of time upstream communications must be halted. Consequently, the negative impact of ranging on the throughput of communicating ONTs is lessen by using a shortened ranging window.

In contrast, when the location of the ONT is unknown, it possible the ONT is located at a possible maximum distance (e.g., 20 Km) away from the OLT. As such, to accommodate this maximum distance, a maximal ranging window must used.

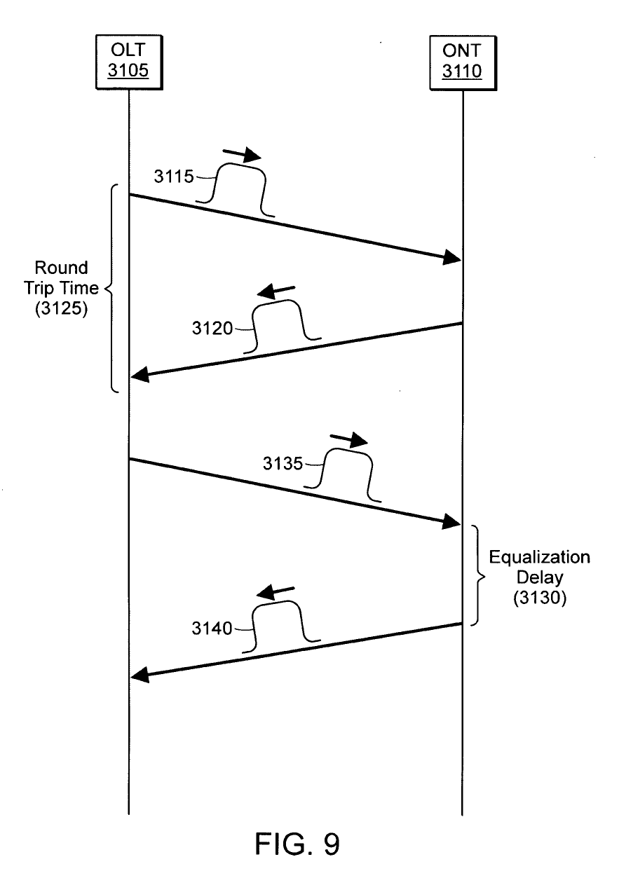

FIGS. 9-25 illustrate example embodiments of an aspect of the present invention in which a transport layer ranging window has a longer duration than a physical layer ranging window. The transport layer ranging window defines a range within which an ONT can respond to a ranging request without affecting upstream communications from other ONT's on the ODN, and the physical layer ranging response defines a time within which a receiver in the OLT is enabled to receive a ranging response from the ONT. By keeping the transport layer ranging window sufficiently long in duration, ranging responses from ONT's at unspecified ranges can be captured. By shortening the physical layer ranging window, errors due to noise or faulty ONT output power can be reduced.

FIG. 9 is a message diagram illustrating an OLT 3105 ranging an ONT 3110. To range the ONT 3110, the OLT 3105 transmits a ranging request 3115. The ONT 3110, in response to the transmitted ranging request 3115, transmits a ranging response 3120. The OLT 3105, having received the ranging response 3120, determines a metric associated with the ranging response 3120 for use in connection with upstream communications between the OLT 3105 and the ONT 3110. For example, a round-trip time 3125 may be determined, where the determined round-trip time 3125 represents a time from when the OLT 3105 transmits the ranging request 3115 to the time the OLT 3105 receives the ranging response 3120. It should be understood that ranging cycles may be calculated other ways, such as a one-way trip time of a ranging request 3115 or a ranging response 3120.

In one embodiment, the OLT 3105 sets at least one parameter, used in connection with upstream communications between the OLT 3105 and the ONT 3110, based on at least one metric associated with the ranging response 3120. For example, the OLT 3105, based on the round-trip time 3125, may set an equalization delay 3130. The OLT 3105 may then send the ONT 3110 the equalization delay 3130 or command the ONT 3110 to set an internal parameter based on the equalization delay 3130. In an example embodiment, the equalization delay 3130 is conveyed via a message 3135. During later communications with the OLT 3105 in this example embodiment, the ONT 3110, in turn, waits for a time according to the equalization delay 3130 before sending upstream communications data 3140. In one embodiment, the ONT 3110 uses the equalization delay 3130 to have the upstream communications data 3140 reach in the OLT 3105 during a predefined timeslot relative to upstream communications data from other ONTs (not shown), as known in the art.

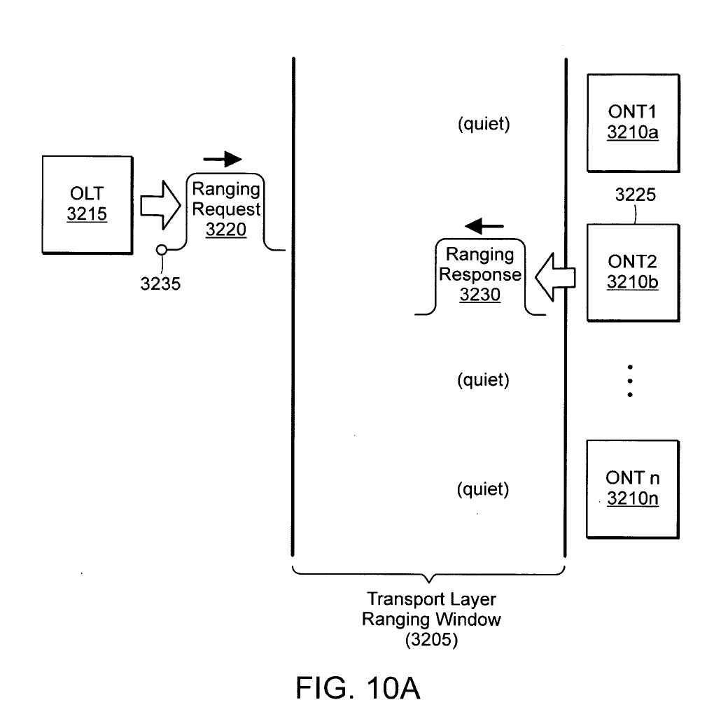

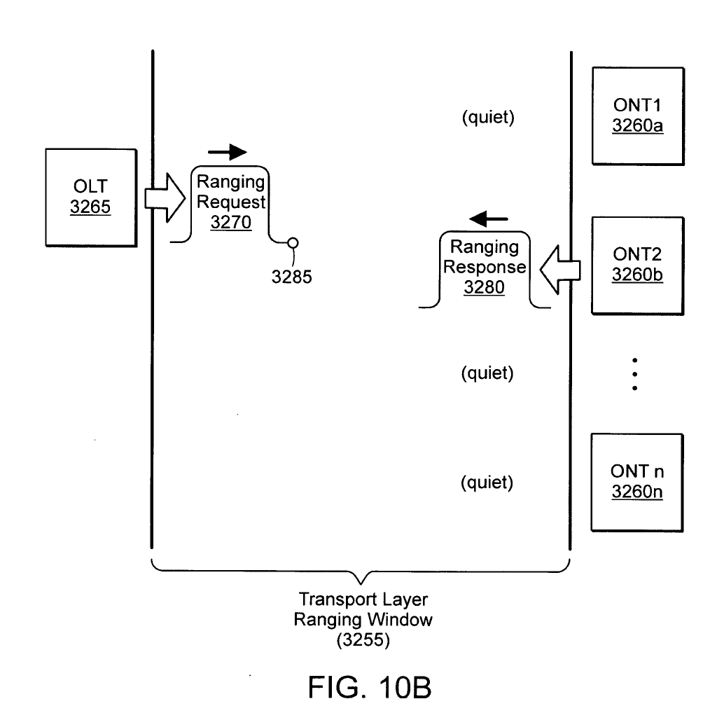

Previously described in reference to FIGS. 3A and 6B, a ranging window is further described in FIGS. 10A and 10B.

FIG. 10A illustrates, in connection with a transport layer ranging window 3205, an OLT 3215 transmitting a ranging request 3220 and an ONT 3225, among a group of ONTs 3210a-n, transmitting a ranging response 3230. During the transport layer ranging window 3205, upstream communications from communicating ONTs 3210a-n are halted (or set in a “quiet” state).

In FIG. 10A, the transport layer ranging window 3205 starts with the OLT 3215 transmitting a last-bit 3235 of the ranging request 3220. Presented differently, the ranging request 3220 is transmitted before the transport layer ranging window 3205 begins. Alternatively, referring to FIG. 10B, a transport layer ranging window 3255 starts with an OLT 3265 transmitting a first-bit 3285 of a ranging request 3270, so the ranging request 3270 and ranging response 3280, are transmitted during the transport layer ranging window 3255. As such, the duration of the transport layer ranging window 3205 of FIG. 10A may be shorter than the duration of the transport layer ranging window 3255 of FIG. 10B. Consequently, upstream communications from ONTs 3210a-n of FIG. 10A may be halted for a shorter period of time than upstream communications from ONTs 3260a-n of FIG. 10B. In other embodiments, the transport layer ranging window 3205 and 3255 of FIGS. 10A and 10B, respectively, are the same duration or the transport layer ranging window 3255 of FIG. 10B is shorter than the one of FIG. 10A.

For the remainder of this disclosure, a ranging request is described as being transmitted during a transport layer ranging window unless otherwise specified. It is noted, however, that example embodiments of the invention are not limited to a transport layer ranging window starting with a first bit of a ranging request being transmitted. Example embodiments of the invention are also applicable to a transport layer ranging window starting with transmission of a last-bit of a ranging request.

As described previously in reference to FIG. 6B, an integrated no-input signal power level may ramp (or increase with time) over a transport layer ranging window. Due to the duration of the transport layer ranging window and ramping the integrated no-input signal power level over this duration, a no-input extinction ratio (see FIG. 5) may be small. In such a case, it may be difficult to distinguish a no-input signal from a zero-bit input signal, possibly leading to upstream communications problems. To minimize this potential source of communication errors, example embodiments of the invention monitor for a ranging response during a portion of the transport layer ranging window rather than during the entire transport layer ranging window.

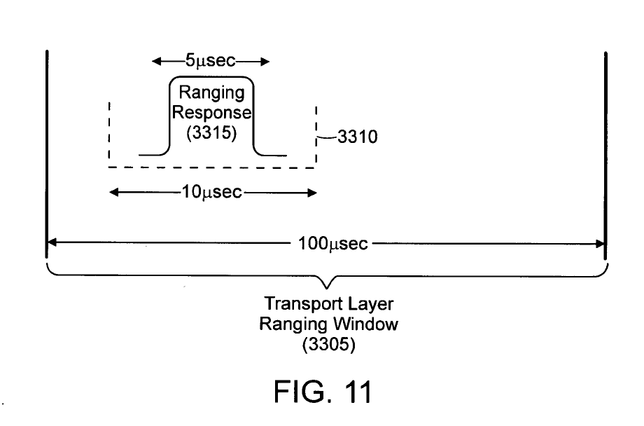

FIG. 11 illustrates a transport layer ranging window 3305 having, for example, a duration of 100 μs (microseconds). A physical layer ranging window 3310 within the transport layer ranging window 3305 may have a duration that is based, in part, on a duration of an expected ranging response 3315. For example, the duration of the physical layer ranging window 3310 may be twice the duration of the ranging response 3315. As such, the duration of the physical layer ranging window 3310 is 10 μs if the duration of the ranging response 3315 is 5 μs. In another example, the duration of the physical layer ranging window 3310 may be some multiple of the duration of the ranging response 3315 plus some time for a delimiter or other overhead (not shown) associated with transmitting the ranging response 3315.

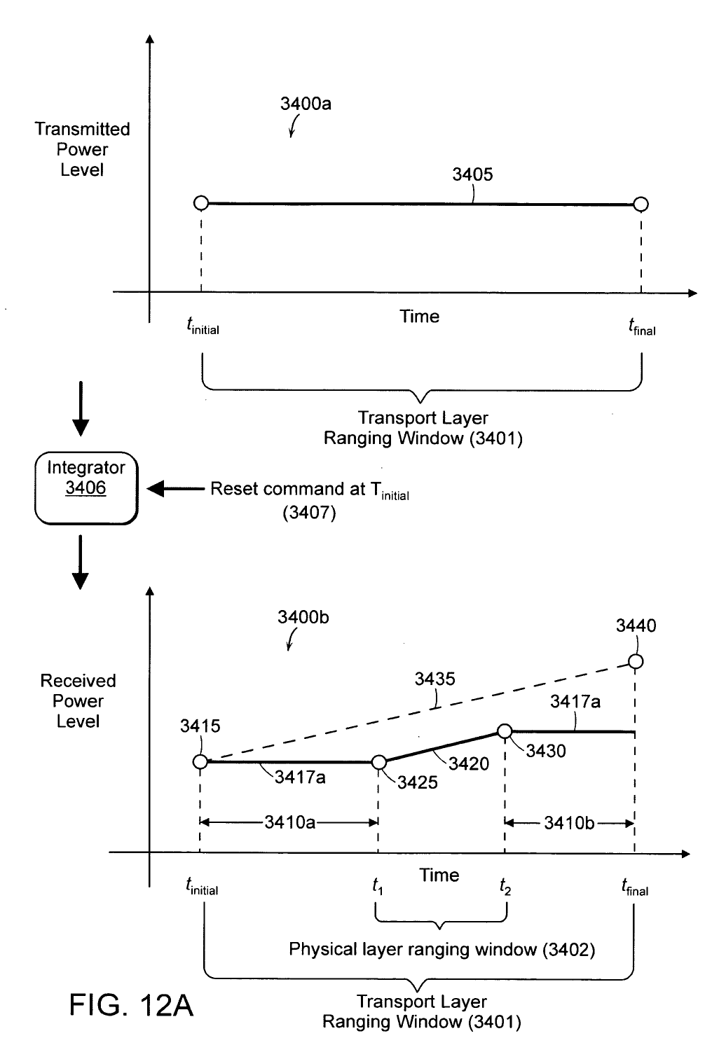

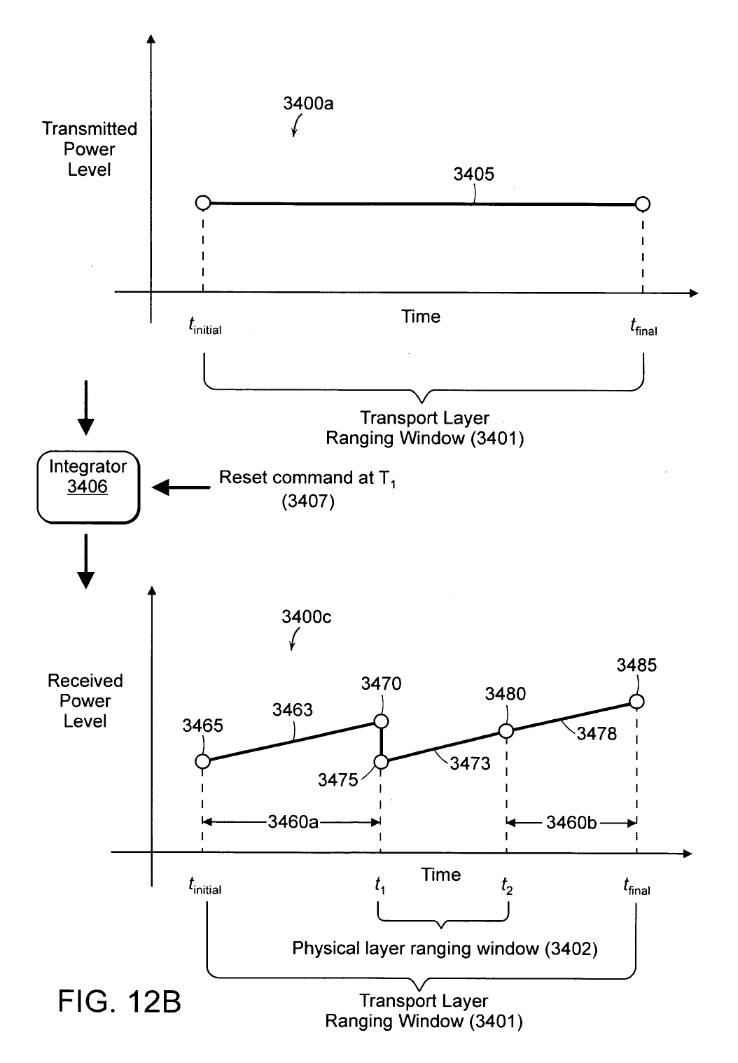

FIG. 12A illustrates a transmitted power level versus time plot 3400a in which, during a transport layer ranging window 3401, an ONT (not shown) transmits a no-input signal power level 3405. A received power level versus time plot 3400b further illustrates, during the transport layer ranging window 3401, an OLT (not shown) receiving the transmitted no-input signal power level 3405.

The transmitted power level versus time plot 3400a indicates the transmitted no-input signal power level 3405 may be constant during the transport layer ranging window 3401. The constant level may be a normal no-input level (e.g., less than −40 dBm) or a faulty low-level (e.g., between −30 dBm and −25 dBm, or higher).

The received power level versus time plot 3400b illustrates the duration of the transport layer ranging window 3401 as being from Tᵢₙᵢₜᵢₐₗ to T_{final}, and the duration of a physical layer ranging window 3402 as being from T₁ to T₂. The duration of the transport layer ranging window 3401 is greater than the duration of the physical layer ranging window 3402, i.e., the time from Tᵢₙᵢₜᵢₐₗ to T_{final} is greater than the time from T₁ to T₂.

In general, the effect of any noise on the receiver increases the longer the physical layer ranging window 3402 is open and decreases the shorter the physical layer ranging window is opened. For purposes of illustrating the effects of noise in a hardware sense, examples in terms of an integrator integrating noise are presented herein, including immediately below. However, the example is not intended to be restrictive in any way.

During the physical layer ranging window 3402 (i.e., from T₁ to T₂), monitoring for ranging response may be enabled. While the monitoring is enabled, a ranging response received during the physical layer ranging window 3402 may be processed.

Additionally, while the monitoring is enabled, the transmitted no-input signal power level 3405 is received and integrated by an integrator 3406 (or other electronics) in a receiver (or transceiver) of the OLT. Consequently, a power level measured from T₁ to T₂ increases over time (or ramps) due to integration. This power level, which may be measured while monitoring is enabled, is referred to herein as an integrated power level associated with monitoring for a ranging response (e.g., 3420 and 3435).

In contrast, during a disabled period 3410a (i.e., from Tᵢₙᵢₜᵢₐₗ to T₁) or 3410b (i.e., from T₂ to T_{final}), monitoring for a ranging response may be disabled. While the monitoring is disabled, a ranging response received may not be processed. Additionally, while monitoring is disabled, the transmitted no-input signal power level 3405 is received, but may not be integrated by the integrator 3406. Consequently, power levels measured from Tᵢₙᵢₜᵢₐₗ to T₁ and from T₂ to T_{final} remain substantially unchanged (e.g., 3417a and 3417b).

At Tᵢₙᵢₜᵢₐₗ, the transmitted no-input signal power level 3405 is received by the OLT at an initial-power level 3415, which is about the no-input power level output by the ONT, less transmission or other losses. Also at Tᵢₙᵢₜᵢₐₗ, the integrator 3406 is reset by a reset command 3407 or other mechanism. During the first disabled period 3410a, the transmitted no-input signal power level 3405 received by OLT is not integrated. As such, the transmitted no-input signal power level 3405 received by the OLT between Tᵢₙᵢₜᵢₐₗ and T₁ remains non-integrated from the initial-power level 3415.

At T₁, the transmitted no-input signal power level 3405 is received by the OLT at a first-power level 3425. Since the transmitted no-input signal power level 3405 is not integrated during the first disabled period 3410a, the initial-power level 3415 and the first-power level 3425 are substantially equal. During the physical layer ranging window 3402, however, the transmitted no-input signal power level 3405 received by OLT is integrated. As such, an integrated power level associated with monitoring for a ranging response 3420 ramps from the first-power level 3425 at T₁ to a second-power level 3430 at T₂.

At T₂, the transmitted no-input signal power level 3405 received by the OLT at the second-power level 3430. During the second disabled period 3410b, the transmitted no-input signal power level 3405 received by the OLT is not integrated. As such, the transmitted no-input signal power level 3405 received by the OLT from T₂ to T_{final} remains substantially unchanged from the second-power level 3430.

In comparison, if monitoring during the transport layer ranging window 3401 (i.e., from Tᵢₙᵢₜᵢₐₗ to T_{final}) is enabled, an integrated power level associated with monitoring for a ranging response 3435 (represented by a dashed line) ramps from the initial-power level 3415 at Tᵢₙᵢₜᵢₐₗ to a final-power level 3440 at T_{final}. Since the duration of the transport layer ranging window 3401 is longer than the duration of the physical layer ranging window 3402, there is more time for the integrated power level 3435 to increase. Consequently, the measured second-power level 3430, at the end of the physical layer ranging window 3402, is less than the final-power level 3440 that would have been measured at the end of the transport layer ranging window 3401 if the physical layer ranging window 3402 was the same length as the transport layer ranging window 3401. Accordingly, the above described consequences of having a small no-input extinction ratio may be minimized by enabling monitoring for a ranging response during a physical layer ranging window rather than during an entire transport layer ranging window.

Alternatively, in FIG. 12B, in a received power level versus time plot 3400c, during a disabled period 3460a (from Tᵢₙᵢₜᵢₐₗ to T₁) or 3460b (from T₂ to T_{final}), monitoring for ranging response may be disabled in a different manner as compared to FIG. 12A. In the embodiment of FIG. 12B, while the monitoring is disabled, a ranging response received may not be processed (e.g., by hardware, firmware, or software), but the transmitted no-input signal power level 3405 may be integrated by an integrator 3406. Consequently, power levels measured from Tᵢₙᵢₜᵢₐₗ to T₁ and from T₂ to T_{final} increase over time (or ramp). These power levels, which may be measured while monitoring is disabled, are referred to herein as integrated power levels (e.g., 3463 and 3478), in comparison to the integrated power level associated with monitoring for a ranging response (3420 and 3435) for FIG. 12A.

At Tᵢₙᵢₜᵢₐₗ, the transmitted no-input signal power level 3405 is received by an OLT at an initial-power level 3465, which is about the no-input power level output by an ONT, less transmission or other losses. During the first disabled period 3460a, the transmitted no-input signal power level 3405 received by the OLT is integrated. As such, beginning at Tᵢₙᵢₜᵢₐₗ, an integrated power level 3463 ramps from the initial-power level 3465 to a first-power level 3470 at T₁.

At T₁, the integrator 3406 is reset by a reset command 3407. Resetting the integrator 3406 resets the integrated power level 3463 from the first-power level 3470 to a reset power level 3475. During the physical layer ranging window 3402, the transmitted no-input signal power level 3405 received by the OLT is integrated. As such, beginning at T₁, an integrated power level 3473 associated with monitoring for a ranging response ramps from the reset power level 3475 to a second-power level 3480 at T₂.

At T₂, the transmitted no-input signal power level 3405 is received by the OLT at the second-power level 3480. During the second disabled period 3460b, the transmitted no-input signal power level 3405 received by the OLT is integrated. As such, beginning at T₂, an integrated power level 3478 ramps from the second-power level 3480 to a final-power level 3485 at T_{final}.

An ONT may be located up to some distance away from an OLT, for example 20 Km. To accommodate such distance, the duration of a transport layer ranging window is set sufficiently long enough to allow the ONT to receive a ranging request, within which an ONT can respond to a ranging request without affecting upstream communications from other ONTs on the ODN, and the OLT to receive a ranging response. As such, the ranging request may be located in time anywhere within the transport layer ranging window. Consequently, the issue is what portion of the transport layer ranging window to monitor for (or to otherwise locate), in time, a ranging response. One approach may be to repeatedly transmit a ranging request and monitor for a ranging response, where physical layer ranging window(s) is/are located in the transport layer ranging window at different location(s) each cycle until the location, in time, of the ranging response is found within the transport layer ranging window.

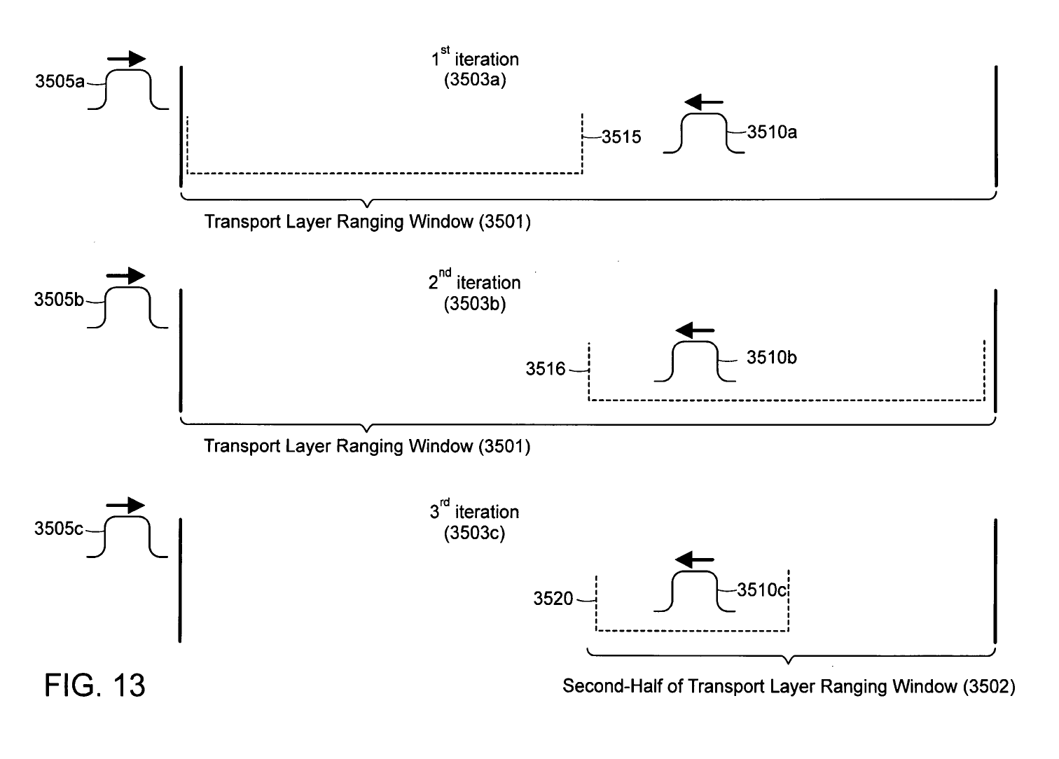

FIG. 13 is a series of timing diagrams illustrating dynamically adjusting a physical layer ranging window in an iterative manner within a transport layer ranging window 3501 to locate a ranging response 3510a-c. By way of example, FIG. 13 illustrates a binary search. One skilled in the art will readily recognize other types of searches are equally applicable, for example, a search based on a hash algorithm. Furthermore, one skilled in the art will readily recognize a transport layer ranging may be approximated through dynamic adjustment of the duration, delay, number, or combination thereof, of a physical layer ranging window. Hardware, firmware, or software may be employed to support or execute the search as understood in the art.

The transport layer ranging window 3501 may be approximated by a first-half physical layer ranging window 3515 and a second-half physical layer ranging window 3516. In a first iteration 3503a, a ranging request 3505a is transmitted, but a ranging response 3510a is not received during the first-half physical layer ranging window 3515. In a second iteration 3503b, a ranging request 3505b is transmitted, and a ranging response 3510b is received during the second-half physical layer ranging window 3516. Accordingly, the ranging response 3510b is located, in time, during a second-half of the transport layer ranging window 3502.

To locate a ranging response in time with more accuracy, the second-half of the transport layer ranging window 3502 may be approximated by a first-quarter physical layer ranging window 3520 and a second-quarter physical layer ranging window (not shown). In a third iteration 3503c, a ranging request 3505c is transmitted, and a ranging response 3510c is received during the first-quarter physical layer ranging window 3520. Accordingly, the ranging response 3510c is located, in time, during a first-quarter of the second-half of the transport layer ranging window 3502. Presently differently, the ranging response 3510c is located, in time, during a third-quarter of the transport layer ranging window 3501.

It should be understood that the example illustrated in FIG. 13 is a simplified example. In practice, hundreds or thousands of attempts to locate a ranging response 3510a-c may be performed.

One skilled in the art will readily recognize the transport layer ranging window 3501 may be even further divided to locate a ranging response, in time, with more accuracy. The number of times a transport layer ranging window is divided in order to locate a ranging response, in time, may depend on the duration of the ranging response. For example, to locate a ranging response of 5 μs, a transport layer ranging window of 100 μs may be divided up to sixteen times to locate the ranging response, in time. In addition to dynamically adjusting the physical layer ranging window within the transport layer ranging window, a transport layer ranging window may also be approximated by shifting one or more physical layer ranging windows.

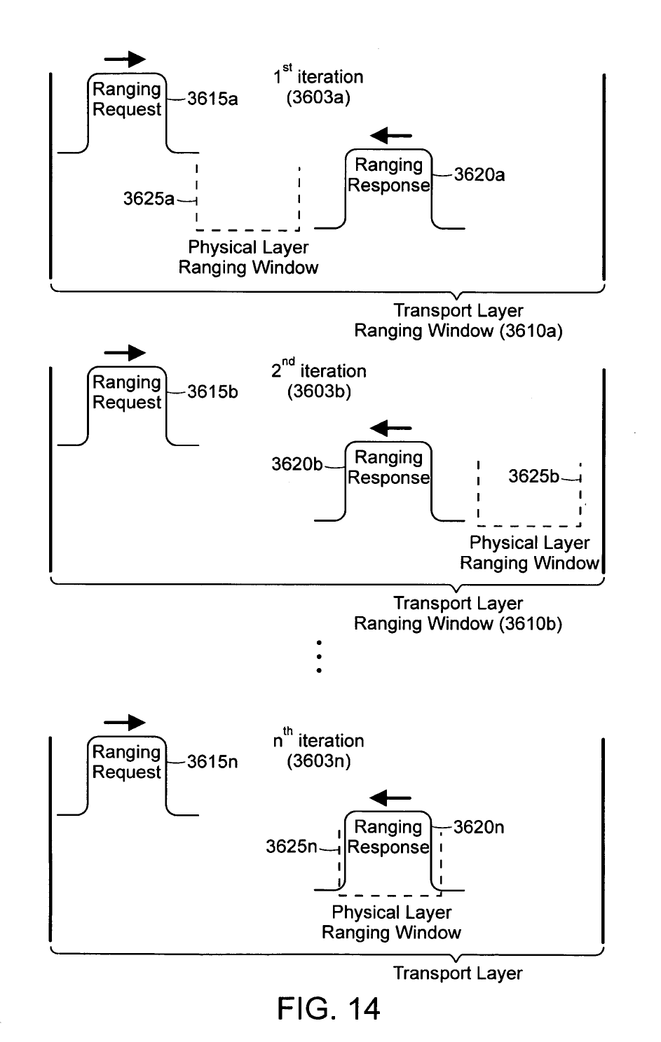

FIG. 14 is a series of timing diagrams illustrating another example of searching for a ranging response by dynamically adjusting a position, in time, of the physical layer ranging window within a transport layer ranging window. In FIG. 14, in a first iteration 3603a, during or otherwise in connection with a transport layer ranging window 3610a, a ranging request 3615a is transmitted, but a ranging response 3620a is not received during a physical layer ranging window 3625a. In a second iteration 3603b, during a transport layer ranging window 3610b, a ranging request 3615b is transmitted. A physical layer ranging window 3625b is shifted, in time, with respect to the first iteration physical layer ranging window 3625a, but a ranging response 3620a remains not received during the shifted physical layer ranging window 3625b. In an nth iteration 3603n, during a transport layer ranging window 3610n, a ranging request 3615n is transmitted. A physical layer ranging window 3625n is shifted, in time, with respect to previous physical layer ranging windows. In this nth iteration 3603n, a ranging response 3620n is received during the shifted physical layer ranging window 3625n.

Having found the ranging response 3620n during the physical layer ranging window 3625n, transmitting a ranging request, monitoring for a ranging response, and shifting a physical layer ranging window may or may not repeat. In one example embodiment, the transmitting, monitoring, and shifting repeat at least until a ranging response is received during a physical layer ranging window. In another example embodiment, the transmitting, monitoring, and shifting repeat for a fixed, variable or otherwise predetermined number of repetitions. In addition to shifting a physical layer ranging window non-incrementally within a transport layer ranging window, a physical layer ranging window may be shifted incrementally across the transport layer ranging window.

In both FIGS. 13 and 14, the physical layer ranging window is set slightly longer in duration than the expected duration of a ranging response to keep a metric, calculated by integrating a no-input signal power level, to an acceptable error level, where the acceptable error level is one within which parameter(s) based upon the metric and used for upstream communications during normal operations do not adversely affect the upstream communications.

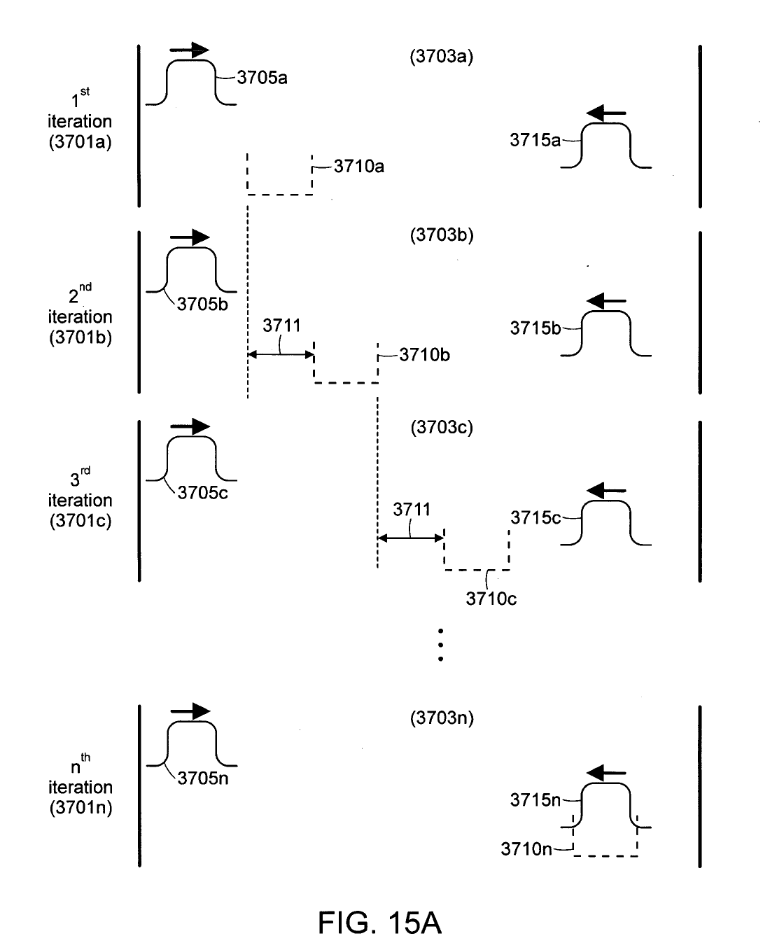

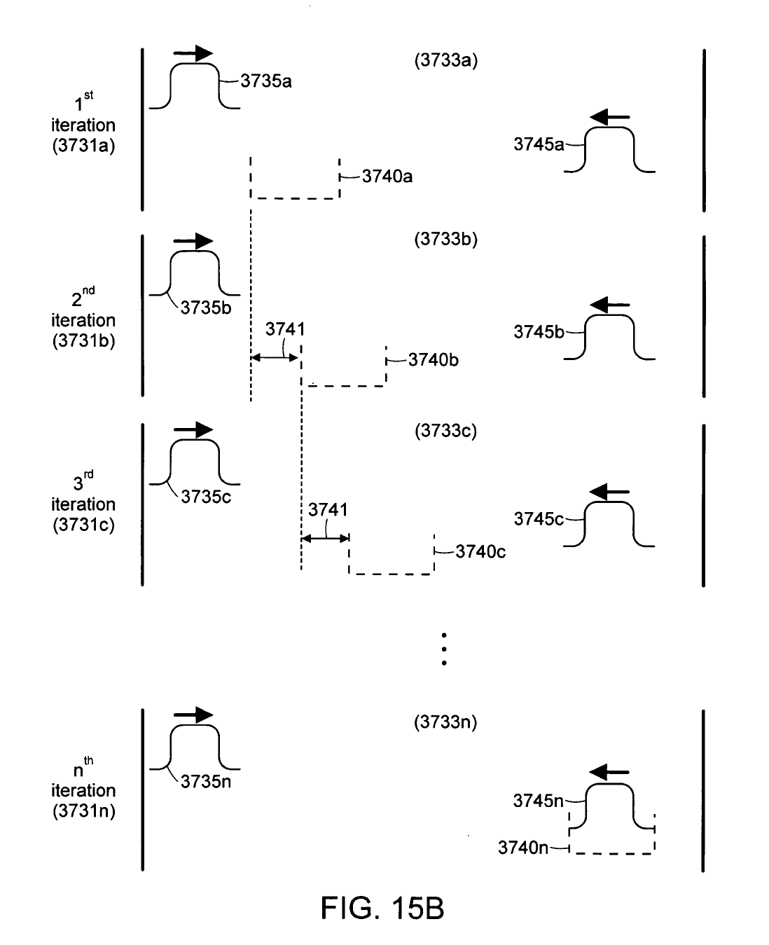

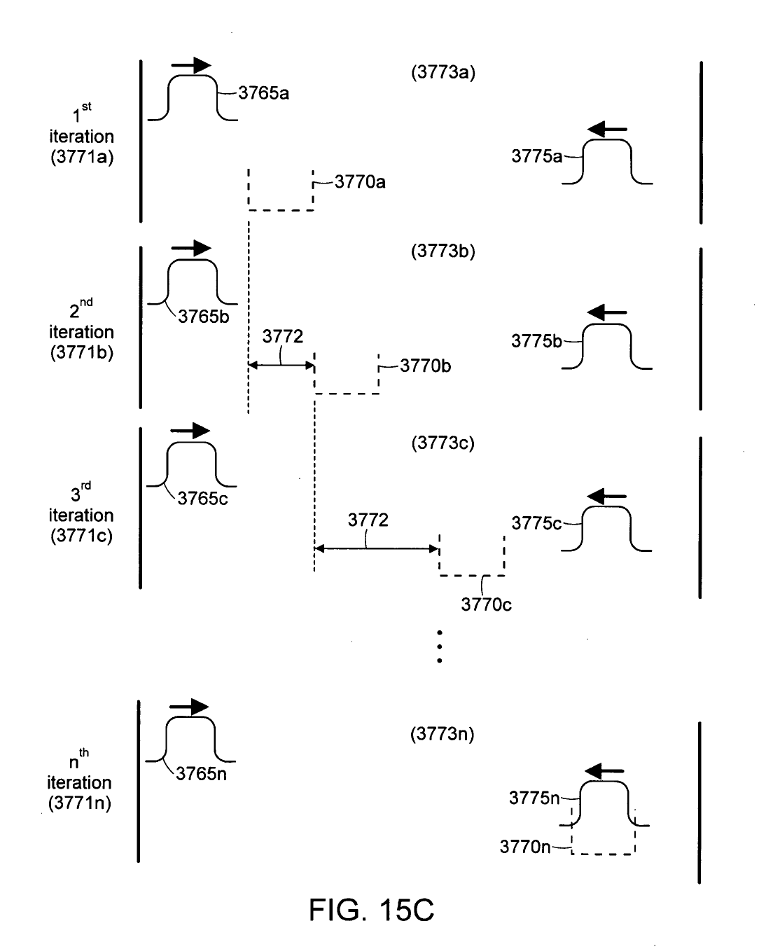

FIG. 15A is a series of timing diagrams illustrating a search technique in which a physical layer ranging window is shifted across a transport layer ranging window in equal steps. In FIG. 15A, in a first iteration 3701a, during a transport layer ranging window 3703a, a ranging request 3705a is transmitted, but a ranging response 3715a is not received during a physical layer ranging window 3710a. In a second iteration 3701b, a ranging request 3705b is transmitted, and a physical layer ranging window 3710b is shifted, in time, relative to the previous physical layer ranging window 3715a, across the transport layer ranging window 3703b by a shift increment 3711. A ranging response 3715b is not received during the shifted physical layer ranging window 3710b. In a third iteration 3701c, a ranging request 3705c is transmitted, and a physical layer ranging window 3710c is again shifted, in time, relative to the previous physical layer ranging window 3710b, across the transport layer ranging window 3703c by the shift increment 3711. Again, a ranging response 3715c is not received during the shifted physical layer ranging window 3710c.

In an nth iteration 3701n, a ranging request 3705n is transmitted in a transport layer ranging window 3703n, and a ranging response 3715n is received during a physical layer ranging window 3710n shifted, in time, relative to a previous ((n−1)th physical layer ranging window (not shown) by the shift increment 3711.

In this embodiment, the shift increment 3711 shifts the physical layer ranging window 3710a-n, in time, by an amount equal to some whole number multiple of the duration of the physical layer ranging window 3710a-n. For example, a physical layer ranging window of 10 μs may be shifted, in time, incrementally by 10 μs, 20 μs, 30 μs, etc. across the transport layer ranging window.

FIG. 15B is a series of timing diagrams which collectively illustrate another example embodiment of searching for a ranging response within a transport layer ranging window. A physical layer ranging window 3740a-n is shifted, in time, by a shift increment 3741. The shift increment 3741 is some fraction of the physical layer ranging window 3740a-n. For example, a physical layer ranging window of 10 μs may be shifted, in time, incrementally by 5 μs, 15 μs, 25 μs, etc. across the transport layer ranging window 3733a-n. From a first iteration through an nth iteration 3731a-n, a ranging request 3735a-n is transmitted, and a physical layer ranging window 3740a-n is shifted by the shifting increment 3741 at least until a ranging response 3745a-n is received during a physical layer ranging window, which occurs in this example during the nth physical layer ranging window 3740n.

In some cases, the FIGS. 15A and 15B physical layer ranging window (PLRW) shift techniques may not result in successful ranging should a ranging response being partially aligned with the physical layer ranging window. One way of preventing this is to overlap any two adjacent ranging windows by an amount greater than or equal to the ranging response to ensure that if the tail end of the ranging response is just missed (e.g., by one PLRW), the very beginning of the ranging response is not missed by the next PLRW.

In general if the PLRW is Y times the duration ranging response (RR) (i.e., PLRW=Y×RR), the PLRW can be shifted no more that RR/(Y−1) in order to guarantee that, if the very last bit of the ranging response is truncated by the current position of the PLRW, the next shifted PLRW does not truncate the very first part of the ranging response.

For example, in reference to FIG. 15A, if the duration of the PLRW is equal to two times (2×) the duration of the ranging response, there is a shift of less than RR of the PLRW. In the FIG. 15B example, if the duration of the PLRW is equal to one and one-half times (1.5×) the duration of the ranging response, there is a shift of less than one-half (0.5) of the RR to a subsequent PLRW.

FIG. 15C is a series of timing diagrams which collectively illustrate another example embodiment of searching for a ranging response within a transport layer ranging window. A physical layer ranging window 3770a-n is shifted, in time, by a variable shift increment 3772. The variable shift increment 3772 shifts the physical layer ranging window 3770a-n, in time, by some amount. The amount shifted may be random or pseudo-random. Optionally, the physical layer ranging window 3770a-n may be shifted, in time, by an amount according a geometric series, a logarithmic series, or other series. As such, from a first iteration through an nth iteration 3771a-n, a ranging request 3755a-n is transmitted, and the physical layer ranging window 3770a-n is shifted in transport layer ranging windows 3773a-n by the variable shifting increment 3772 at least until a ranging response 3775n is received during a physical ranging window, which occurs in this example in the nth physical layer ranging window 3770n.

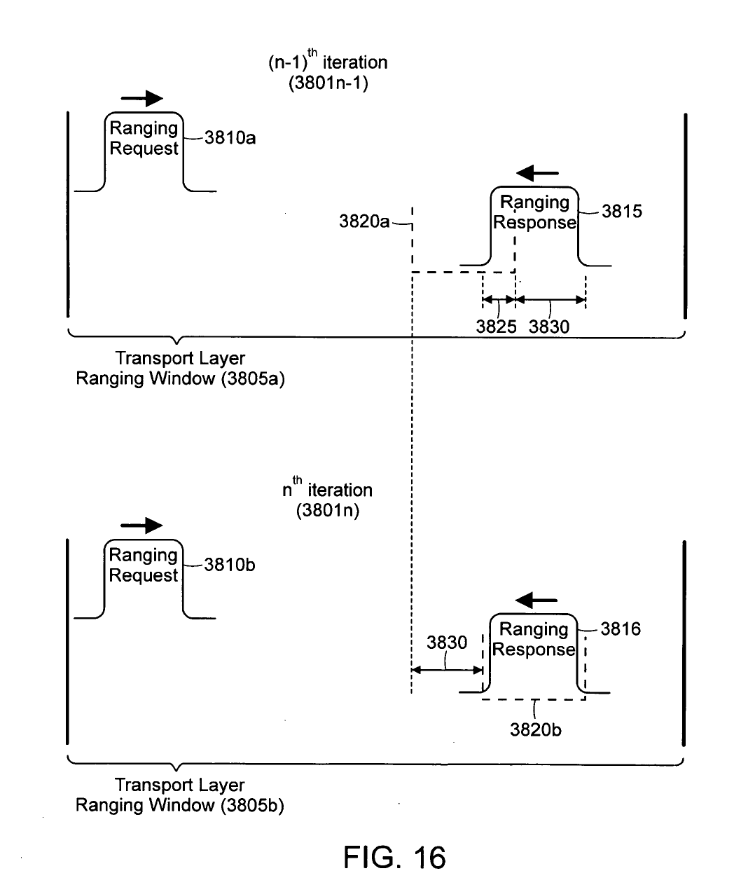

FIG. 16 is a series of timing windows which illustrate an example technique of adjusting timing of a physical layer ranging window in an event only part of a ranging response is received during a physical layer ranging window. In an (n−1)th iteration 3801n−1, during a transport layer ranging window 3805a, a ranging request 3810a is transmitted. During the transport layer ranging window 3805a, a ranging response 3815, in part, is received during a physical layer ranging window 3820a. The portion of the ranging response 3815 received during the physical layer ranging window 3820a is referred to herein as a received portion 3825, while a remaining portion not received is referred to herein as a non-received portion 3830.

In an nth iteration 3801n, during a later transport layer ranging window 3805b, a ranging request 3810b is transmitted, and a physical layer ranging window 3820b is shifted, in time. The physical layer ranging window 3820b is shifted, in time, by an amount expected to result in receiving a ranging response 3816 in full during the physical layer ranging window 3820b. For example, the physical layer ranging window 3820b may be shifted, in time, relative to the (n−1)th physical layer ranging window 3820a, by an amount equal to the non-received portion 3830. Alternatively, the physical layer ranging window 3820b may be shifted, in time, by an amount greater than the non-received portion 3830. In addition to shifting, in time, the physical layer ranging window, in another embodiment, the duration of a physical layer ranging window may be lengthened, after a portion of the ranging response is received, by an amount expected to allow the ranging response to be received during the physical layer ranging window.

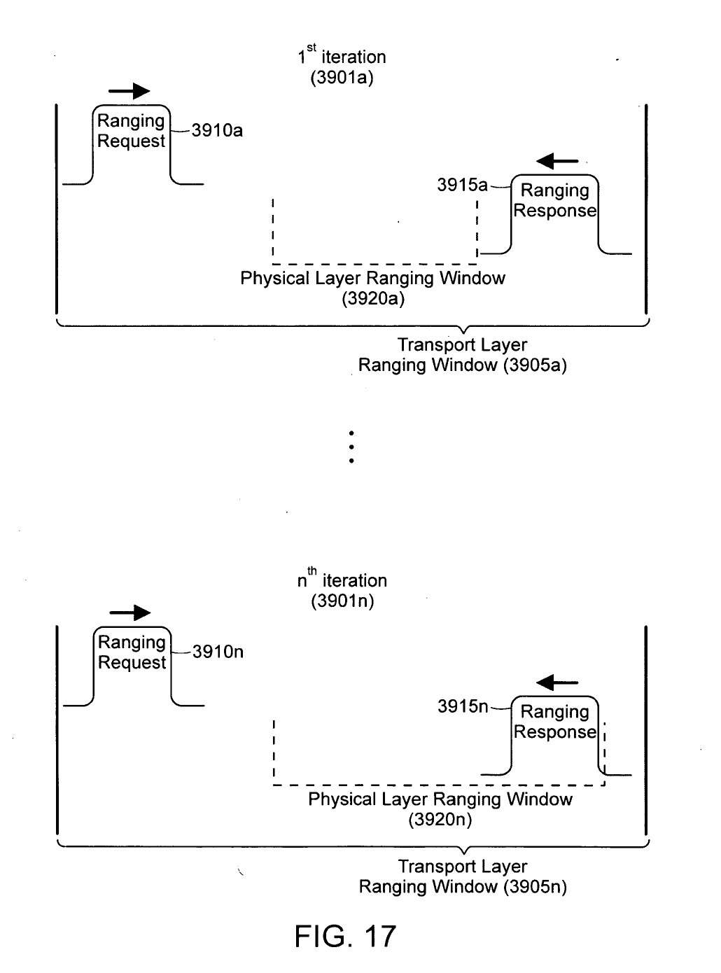

FIG. 17 is a series of timing diagrams which illustrate a search technique for monitoring for a ranging response by adjusting a length of a physical layer ranging window in a dynamic manner. In a first iteration 3901a, during a transport layer ranging window 3905a, a ranging request 3910a is transmitted. During the transport layer ranging window 3905a, a ranging response 3915a is not received during a physical layer ranging window 3920a. In this embodiment, the duration of the physical layer ranging window 3920a is lengthened at least until a ranging response is received during the lengthened physical layer ranging window.

In an nth iteration 3901n, during a transport layer ranging window 3905n, a ranging request 3910n is transmitted, and a physical layer ranging window 3820n is shown in a lengthened state relative to the length of the physical layer ranging window 3920a of the first iteration 3901a. During the transport layer ranging window 3905n, a ranging response 3915n is received during the lengthened physical layer ranging window 3920n.

In another embodiment, in addition to lengthening the duration, once the timing of the ranging response 3915n is known to be within the transport layer ranging window 3905n and the physical layer ranging window 3920n, the physical layer ranging window 3920n can be shortened to reduce noise or integration effects associated with monitoring for the ranging response 3915n.

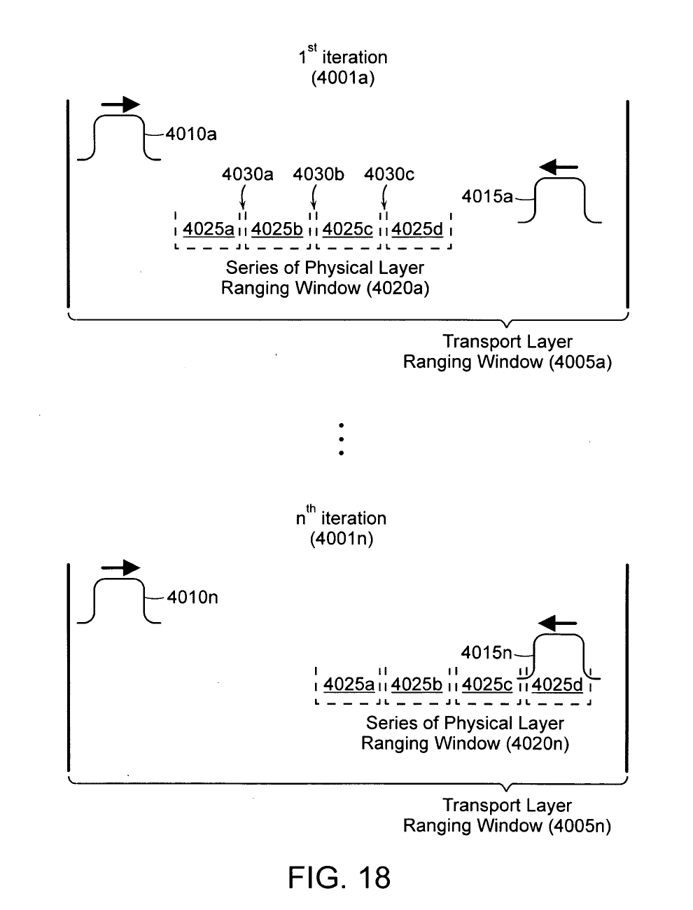

FIG. 18 is a series of timing diagrams illustrating use of a series of physical layer ranging windows to monitor for a ranging response. In a first iteration 4001a, during a transport layer ranging window 4005a, a ranging request 4010a is transmitted from an OLT to an ONT. During the transport layer ranging window 4005a, a ranging response 4015a from the ONT is not received by the OLT during a series of physical layer ranging windows 4020a, which includes multiple physical layer ranging windows 4025a-d.

In an nth iteration 4001n, during a transport layer ranging window 4005n, a ranging request 4010n is transmitted, and a series of physical layer ranging windows 4020n is shown shifted relative to the series of physical layer ranging windows 4020a of the first iteration 4001a. During the transport layer ranging window 4005n, a ranging response 4015n is received during a physical layer ranging window 4025d in the shifted series of physical layer ranging windows 4020n.

Each series of the physical layer ranging windows 4020a-n may be defined by more than one physical layer ranging window 4025a-d. During each window 4025a-d in the series of physical layer ranging windows 4020a-n, monitoring is enabled (described above in reference to FIG. 12) for an amount of time equal to or for a portion of each physical layer ranging window 4025a-d. Each physical layer ranging window 4025a-d of the series of physical layer ranging windows 4020a-n may be equally “sized,” i.e., similar in duration. Alternatively, each physical layer ranging window of the series of physical layer ranging windows may be differently “sized,” i.e., differing in duration. As such, monitoring for a ranging response during the series of physical layer ranging windows may be enabled for regular or irregular durations within the series 4020a-n.

Additionally, in the series of physical layer ranging windows 4020a-n, between each physical layer ranging window 4025a-d, there may be gaps 4030a-c. During each gap 4030a-c, monitoring for a ranging response is disabled (described above in reference to FIGS. 12A and 12B). In other words, between adjacent physical layer ranging windows (e.g., 4025a and 4025b) in the series of physical layer ranging windows 4020a-n, monitoring for ranging response is enabled, then disabled, then enabled again, and so on. During each gap 4030a-c, monitoring may be reset (for example, an integrator may be “zeroed”), including at the beginning or the end of each of the gaps 4030a-c.

Furthermore, each physical layer ranging window may be equally “spaced” from one another with such a gap. That is, monitoring for a ranging response may be disabled for a similar duration between adjacent physical layer ranging windows. Alternatively, adjacent physical layer ranging windows may be unequally “spaced” from one other, thus disabling monitoring for different durations. As such, monitoring for a ranging response during a series of physical layer ranging windows may be disabled for regular or irregular durations within the series.

It should be understood that there may be more than four physical layer ranging windows 4025a-d in each series 4020a-n. For example, there may be tens, hundreds, thousands, or millions of physical layer ranging windows in each series 4020a-n depending on an expected length of ranging response, length of transport layer ranging windows 4005a-n, and implementation features.

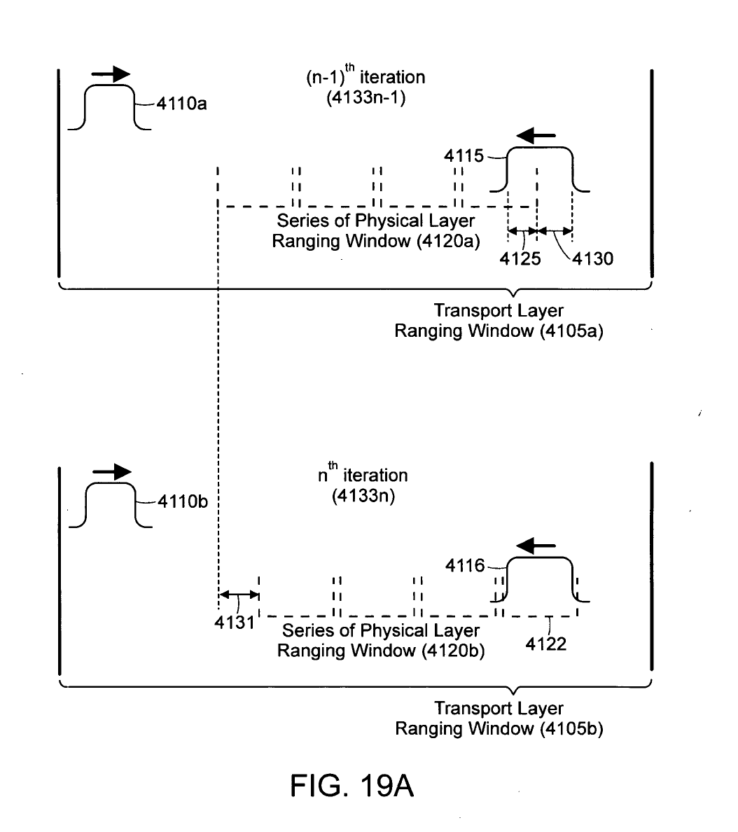

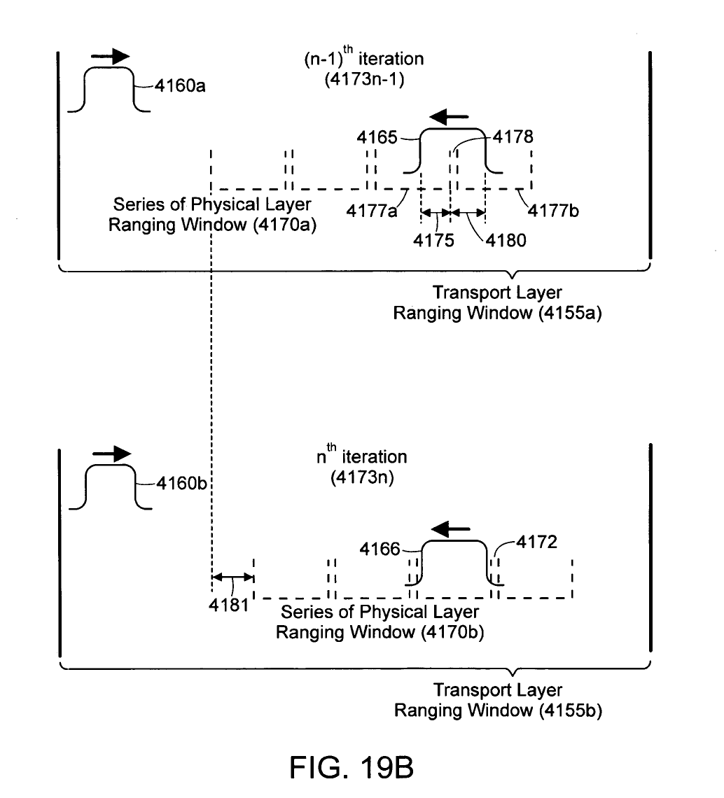

FIG. 19A is a series of timing diagrams illustrating a shift in a series of physical layer ranging windows to locate a ranging response in full. In an (n−1)th iteration 4133n−1, during a transport layer ranging window 4105a, a ranging request 4110a is transmitted. During the transport layer ranging window 4105a, a ranging response 4115 is received in part during a series of physical layer ranging windows 4120a. The part of the ranging response 4115 received is referred to herein as a received portion 4125, while the remaining portion not received is referred to herein as a non-received portion 4130. The non-received portion may fall within a gap between the physical layer ranging windows or it may arrive after the physical layer ranging windows are halted following receipt of the received portion 4125.

In an nth iteration 4133n, during a later transport layer ranging window 4105b, a ranging request 4110b is transmitted, and a series of physical layer ranging windows 4120b is shifted, in time, relative to the earlier series 4120a. The series of physical layer ranging windows 4120b is shifted, in time, by an amount expected to result in receiving a ranging response 4116 in full during a physical layer ranging window 4122 in the series of physical layer ranging windows 4120b. For example, the series of physical layer ranging windows 4120b may be shifted, in time, by an amount 4131 equal to an amount of time of the non-received portion 4130. Alternatively, the series of physical layer ranging windows 4120b may be shifted, in time, by an amount greater than the non-received portion 4130 but still allowing the ranging response 4116 to fall within the physical layer ranging window 4122.

FIG. 19B is a series of timing diagrams further illustrating shifting a series of physical layer ranging windows to locate a ranging response in full. In an (n−1)th iteration 4133n−1, during a transport layer ranging window 4155a, a ranging request 4160a is transmitted. During the transport layer ranging window 4155a, a ranging response 4165 is received in part during a series of physical layer ranging windows 4170a. A first received portion 4175a of the ranging response 4165 is received during a first physical layer ranging window 4177a, while a remaining portion is not received during the first physical layer ranging window 4177a. The remaining portion is referred to herein as a non-received portion 4180. The non-received portion 4180 may be received during a gap 4178 (see FIG. 18) and/or during another physical layer ranging window 4177b of the series 4170a.

In an nth iteration 4173n, during a later transport layer ranging window 4155b, a ranging request 4160b is transmitted, and a series of physical layer ranging windows 4170b is shifted, in time, relative to the (n−1)th iteration series 4170a. The series of physical layer ranging windows 4170b is shifted, in time, by an amount 4181 expected to result in receiving a ranging response 4166 in full during one physical layer ranging window 4172 of the series of physical layer ranging windows 4170b. For example, the series of physical layer ranging windows 4170b may be shifted, in time, by an amount 4181 equal to an amount of time of the non-received portion 4180. Alternatively, the series of physical layer ranging windows 4170b may be shifted, in time, by an amount greater than the amount of time of the non-received portion 4180 but not more than an amount that allows for receipt within the window 4172.

In an alternative embodiment, the series of physical layer ranging windows 4170b may be replaced with a subset or just one physical layer ranging window once timing of the ranging response within the transport layer ranging window 4155b is approximately known.

An ability to detect a partial response may be related to noise reduction gained by decreasing a size of the physical layer ranging window. In such a case, an optional, generalized, search methodology might be as follows: 1. reduce a size of the physical layer ranging window until the presence of a ranging response can be identified and located; and 2. further shift and reduce the size of the physical layer ranging window until the ranging response can be precisely captured. The presumes that the noise sensitivity associated with detecting and locating presence of a ranging response in full or in part is less than that for completely processing a ranging response.

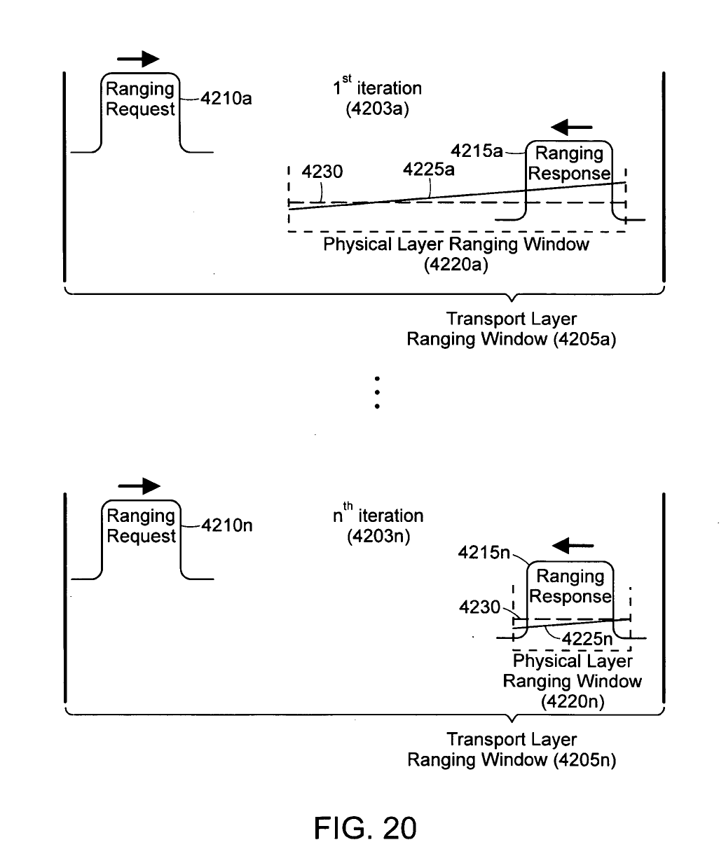

FIG. 20 is a series of timing diagrams that superimposes effects in an OLT of integration of no-input signal power while waiting to receive a ranging response from an ONT. In a first iteration 4203a, during a transport layer ranging window 4205a, a ranging request 4210a is transmitted. During the transport layer ranging window 4205a, the OLT monitors for a ranging response 4215a during a physical layer ranging window 4220a. During the physical layer ranging window 4220a, the OLT integrates and measures a power level 4225a associated with monitoring for a ranging response. The measured power level 4225a associated with monitoring for a ranging response may exceed a threshold 4230 (discussed above in reference to FIG. 7B) due to a long period of integration.

If the measured power level 4225a exceeds the threshold 4230, the physical layer ranging window 4220a is reduced in duration in a next iteration. In this example embodiment, transmitting a ranging request 4210a, monitoring for a ranging response 4215a, and reducing the duration of the physical layer ranging window 4220a repeats at least until the measured power level 4225a associated with monitoring for the ranging response 4215a is below the threshold 4230.

Continuing to refer to FIG. 20, in an nth iteration 4203n, during a transport layer ranging window 4205n, a ranging request 4210n is transmitted, and a physical layer ranging window 4220n is reduced in duration relative to the physical layer ranging window 4220a of the first iteration 4203a, and possibly other previous iterations (not shown). During the transport layer ranging window 4205n, the OLT (not shown) monitors for a ranging response 4215n during the reduced physical layer ranging window 4220n. The OLT measures a power level on an upstream communications path associated with monitoring for ranging response 4215n. In the nth iteration 4203n, the measured power level 4225n associated with monitoring for the ranging response 4215n is below the threshold 4230 due to a reduced integration time, based on the length of time of the physical layer ranging window 4220n.

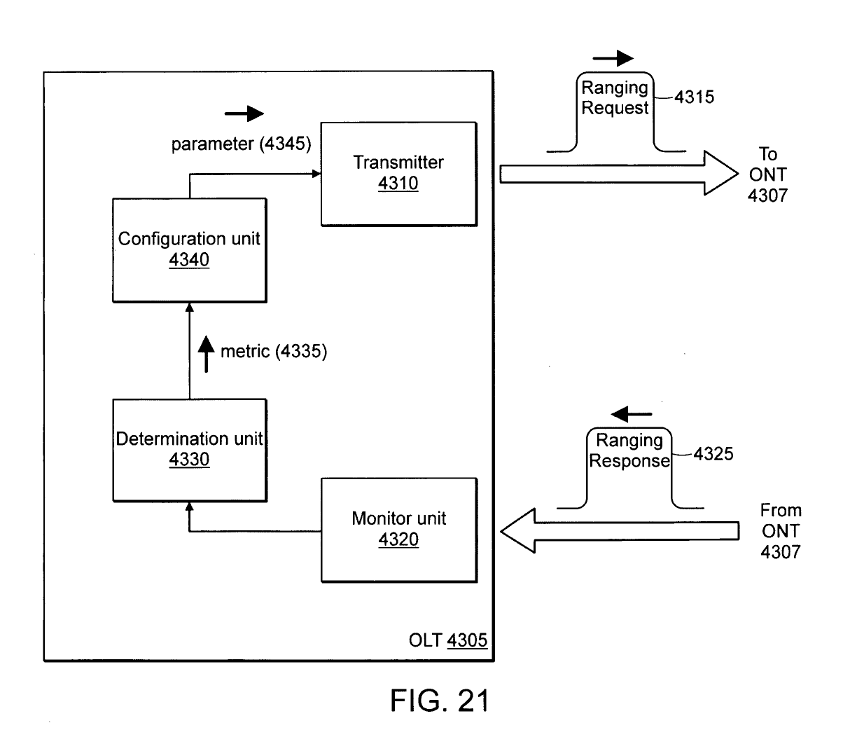

FIG. 21 is a block diagram of an exemplary OLT 4305 in communication with an ONT 4307. A transmitter 4310 transmits a ranging request 4315 to the ONT 4307. A monitor unit 4320 monitors for a ranging response 4325 from the ONT 4307. Associated with the monitoring for the ranging response 4325, a determination unit 4330 determines at least one metric 4335. The at least one metric 4335 is used in connection with upstream communications between the ONT 4307 and the OLT 4305. Based on the determined metric 4335, a configuration unit 4340 sets at least one parameter 4345. The set parameter 4345 is used in connection with upstream communications between the ONT 4307 and the OLT 4305. The transmitter 4310 may send the at least one parameter 4345 to the ONT 4307 so that the ONT 4307 may further communicate (see FIG. 9).

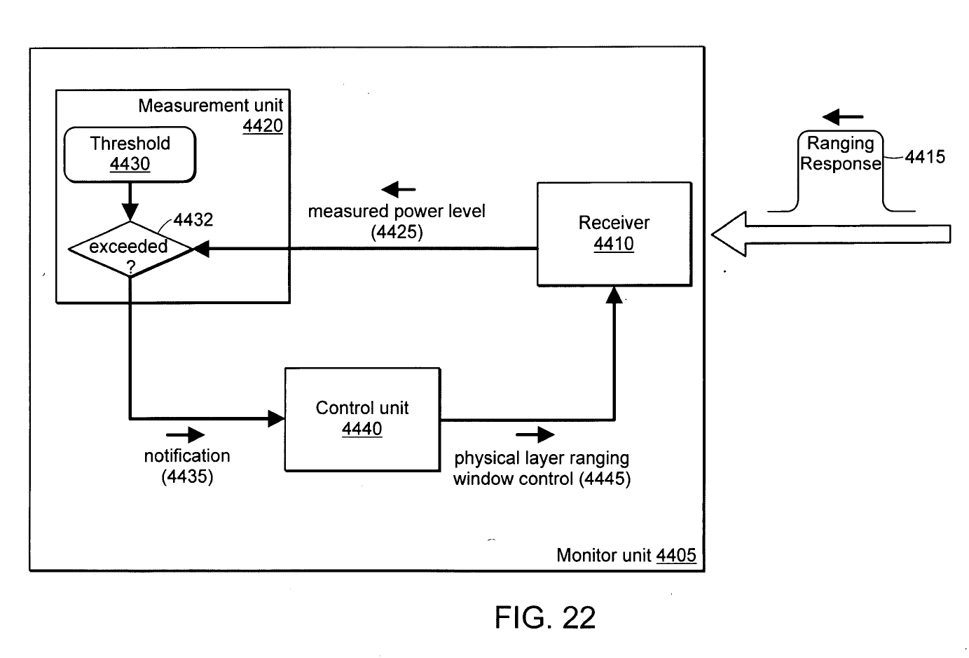

FIG. 22 is a block diagram illustrating an exemplary monitor unit 4405, which may be used in supporting example embodiments of the invention. The monitor unit 4405 may include a receiver 4410, a measurement unit 4420, and a control unit 4440. Alternatively, some or all of the aforementioned components may not be co-located in the monitor unit 4405, but may be remotely located and connected via a communications bus (not shown).

In operation of this example monitor unit 4405, the receiver 4410 may monitor for a ranging response 4415. In monitoring for the ranging response 4415, the measurement unit 4420 may measure a power level 4425 associated with monitoring for the ranging response 4415. The measurement unit 4420 may further compare the measured power level 4425 against a threshold 4430 (discussed in detail in reference to FIG. 7B). If the threshold 4430 is exceeded 4432, a notification 4435 may be sent to the control unit 4440. In response to the notification 4435, the control unit 4440 may issue a physical layer ranging window control 4445 to the receiver 4410. The receiver 4410 may respond by shifting, in time, at least one physical layer ranging window (not shown). Alternatively, the receiver 4410 may respond by enlarging or reducing the duration of at least one physical layer ranging window.

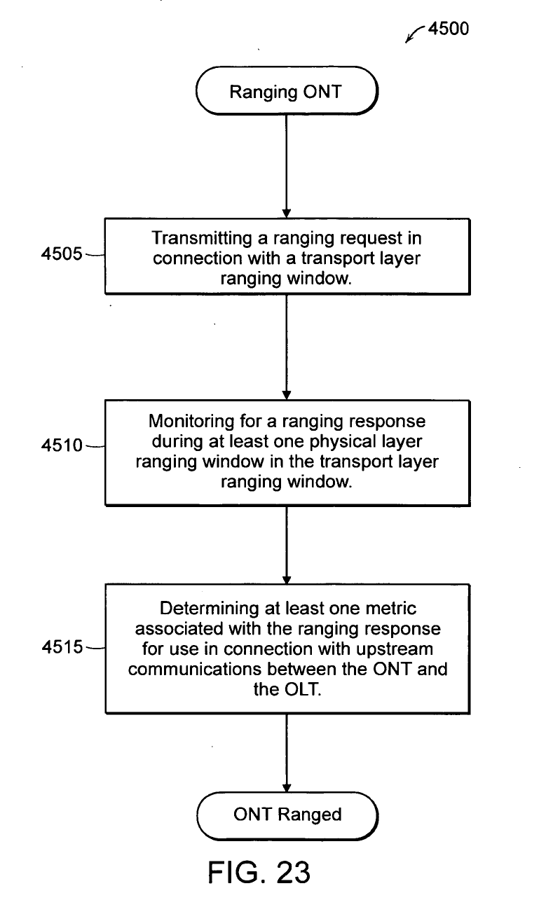

FIG. 23 is a flow diagram illustrating an exemplary process 4500 for ranging an ONT in a passive optical network in accordance with an example embodiment of the invention. In connection with (i.e., before or during) a transport layer ranging window, a ranging request is transmitted (4505) from an OLT. A ranging response is monitored for (4510) during at least one physical layer ranging window in the transport layer ranging window. From the monitoring (4510), at least one metric associated with the monitored ranging response is determined (4515). The determined metric is used in connection with upstream communications between the ONT in the OLT.

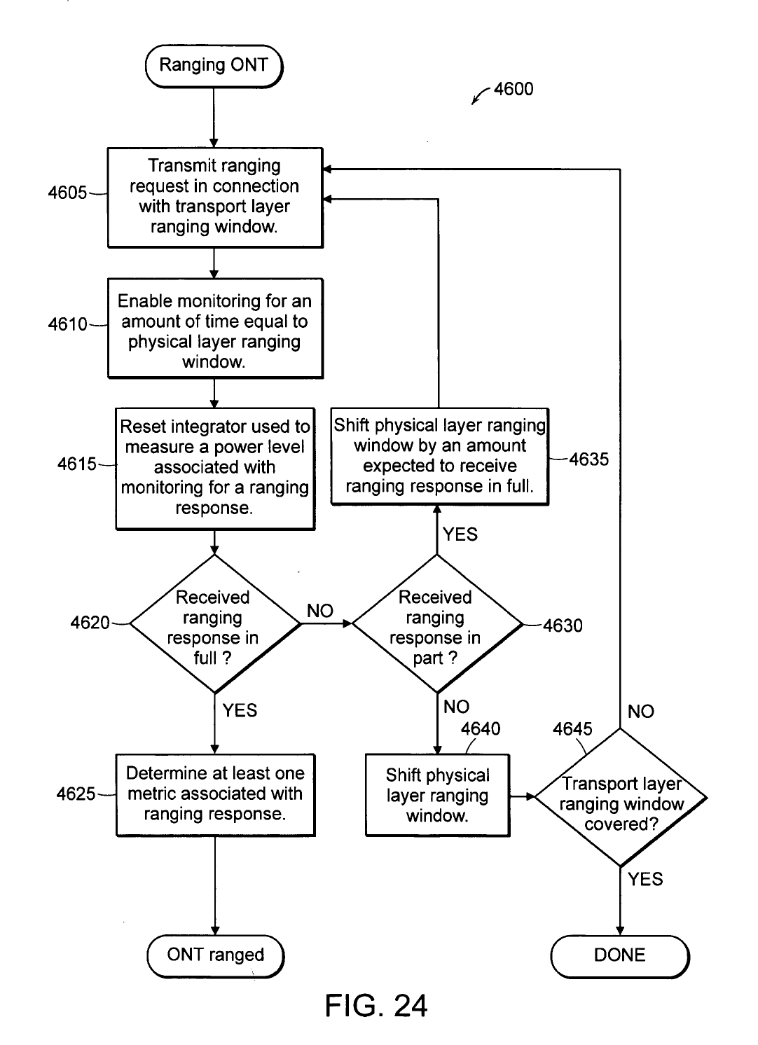

FIG. 24 is a flow diagram illustrating an exemplary process 4600 for ranging an ONT in a passive optical network in accordance with an example embodiment of the invention. In connection with (i.e., before or during) a transport layer ranging window, a ranging request is transmitted (4605) from an OLT. Monitoring for a ranging response is enabled (4610) for an amount of time equal to a physical layer ranging window, or less than a physical layer ranging window where possible in some network applications. An integrator (or other circuitry) used to measure a power level associated with monitoring for a ranging response is reset (4615) at the beginning of a physical layer ranging window or the start of the monitoring. If a ranging response is detected or otherwise received (4620) during a physical layer ranging window, at least one metric associated with the ranging response is determined (4625).

If the ranging response is not monitored (4620), but is received in part (4630), a physical layer ranging window is shifted (4635) by an amount expected to receive the ranging response in full during a physical layer ranging window in a later transport layer ranging window. The process 4600 returns to transmit (4605) a ranging request during a next transport layer ranging window.

If the ranging response is not found (4620) and not received in part (4630), a physical layer ranging window is shifted (4640). The physical layer ranging window may be shifted incrementally (in whole number, fractional, or variable increments) across a transport layer ranging window. After shifting a physical layer ranging window (4640), if the transport layer ranging window is not yet covered (4645) by the physical layer ranging window (i.e., monitoring across the transport layer ranging window is not complete and a ranging response has not yet been found), the process 4600 returns to transmit a ranging request (4605) and monitor (4610 and 4615) for a ranging response.

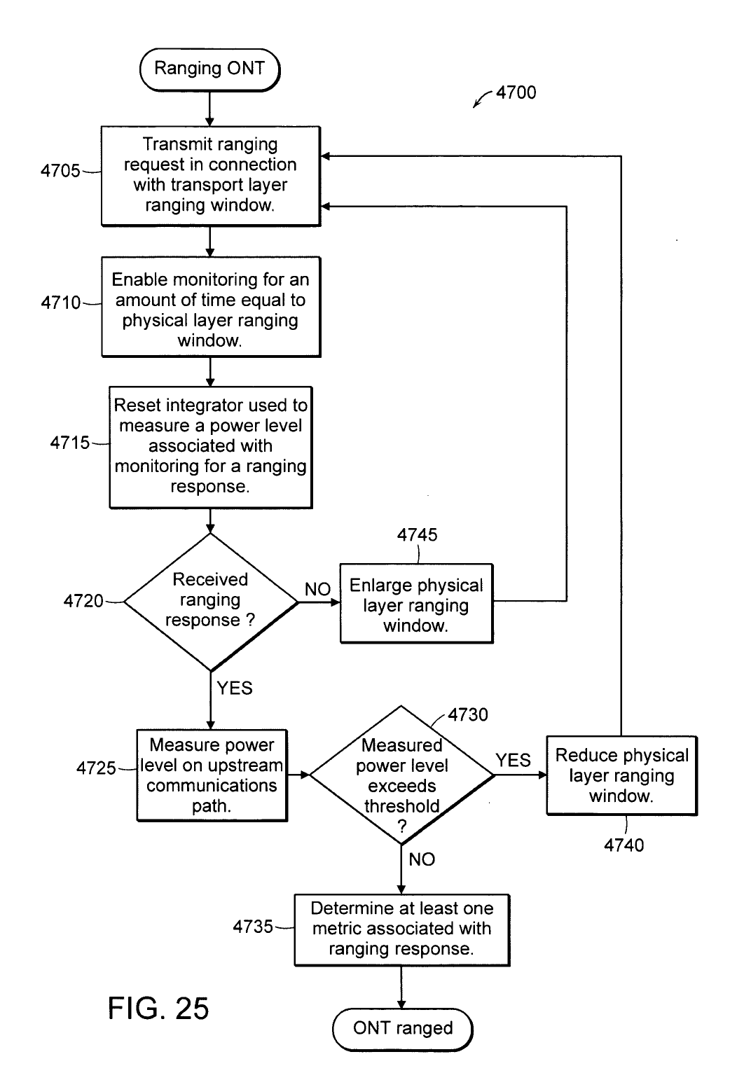

FIG. 25 is a flow diagram illustrating an exemplary process 4700 for ranging an ONT in a passive optical network in accordance with an example embodiment of the invention. In connection with (i.e., before or during) a transport layer ranging window, a ranging request is transmitted (4705) from an OLT. Monitoring for a ranging response is enabled (4710) for an amount of time equal to at least one physical layer ranging window. An integrator (or other circuitry) used to measure a metric, such as a power level, associated with monitoring for a ranging response is reset (4715) at the beginning of a physical layer ranging window or the start of the monitoring.

If a ranging response is monitored (4720) or otherwise received during a physical layer ranging window, a metric, such as power level, associated with the monitoring is measured (4725). If the measured metric does not exceed a threshold (4730), at least one metric associated with the ranging response is determined (4735). The ONT is consequently ranged.

If, however, the measured metric exceeds a threshold (4730), a physical layer ranging window may be reduced in duration (4740). In this example embodiment, the process 4700 repeats at least until the metric associated with monitoring for a ranging response, measured during the reduced physical layer ranging window, is less than the threshold.

If a ranging response is not received (4720) during a physical layer ranging window, the physical layer ranging window may be enlarged in duration (4745). The process 4700 repeats at least until a ranging response is received during the enlarged physical layer ranging window.

The systems of FIGS. 21 and 22 and flow diagrams of FIGS. 23-25 may be implemented in the form of software, firmware, or hardware. If implemented in software, the software may be any applicable software language that can be stored on a computer readable medium, such as RAM or ROM, or distributed via a computer network. A general purpose or application specific processor may load and execute the software, causing the processor to be configured to operate in a manner as disclosed herein.

While this invention has been particularly shown and described with references to example embodiments thereof, it will be understood by those skilled in the art that various changes in form and details may be made therein without departing from the scope of the invention encompassed by the appended claims.

For example, although described as “cards” herein, it should be understood that PON cards, OLT cards, or ONT cards may be systems or subsystems without departing from the principles disclosed hereinabove.

Further, although described in reference to a passive optical network, the same or other example embodiments of the invention may be employed in an active optical network, data communications network, wireless network (e.g., between handheld communications units and a base transceiver station), or any other type of network.

In addition, the flow diagrams (e.g., FIGS. 23-25) may include more or fewer blocks, be arranged differently, or be represented differently. It should be understood that implementation may define the flow diagrams and number of flow diagrams illustrating execution of embodiments of the present invention.

What is claimed is:

1. A method for ranging an Optical Network Terminal (ONT) in a Passive Optical Network (PON), the method comprising:
transmitting a ranging request to an ONT in connection with a transport layer ranging window;
monitoring for a ranging response from the ONT during at least one physical layer ranging window within the transport layer ranging window, the transport layer ranging window having a duration longer than the physical layer ranging window; and
determining at least one metric associated with the ranging response for use in connection with upstream communications between the ONT and the OLT.

2. The method of claim 1 further comprising setting at least one parameter, used in connection with upstream communications between the ONT and OLT, based on the at least one metric associated with the ranging response.

3. The method of claim 1 further comprising enabling the monitoring for a ranging response for an amount of time equal to the physical layer ranging window.

4. The method of claim 3 wherein enabling the monitoring for a ranging response includes resetting integration associated with monitoring for a ranging response at a beginning of the physical layer ranging window.

5. The method of claim 1 further comprising:
measuring a no-input signal metric on an upstream communications path during the physical layer ranging window;
reducing the physical layer ranging window if the measured no-input signal metric on the upstream communications path exceeds a threshold; and
repeating the transmitting, monitoring, and reducing at least until the measured no-input signal metric is less than the threshold.

6. The method of claim 1 wherein transmitting a ranging request and monitoring for a ranging response repeats (i) at least until a ranging response is received during the physical layer ranging window, wherein monitoring for a ranging response includes dynamically adjusting the physical layer ranging window in an iterative manner, or (ii) until determining a ranging response is not within the transport layer ranging window.

7. The method of claim 1 wherein transmitting a ranging request and monitoring for a ranging response repeats (i) at least until a ranging response is received during the physical layer ranging window, wherein monitoring for a ranging response includes shifting the physical layer ranging window within the transport layer ranging window at least until a ranging response is received during the physical layer ranging window, (ii) until determining a ranging response is not within the transport layer ranging window.

8. The method of claim 7 wherein shifting the physical layer ranging window includes shifting the physical layer ranging window incrementally across the transport layer ranging window (i) at least until a ranging response is received during the physical layer ranging window or (ii) determining a ranging response is not within the transport layer ranging window.

9. The method of claim 7 wherein, in an event of receiving a ranging response in part during the physical layer ranging window, shifting the physical layer ranging window includes shifting the physical layer ranging window by an amount expected to result in receiving a ranging response in full during the physical layer ranging window during a later transport layer ranging window.

10. The method of claim 1 wherein transmitting a ranging request and monitoring for a ranging response repeats (i) at least until a ranging response is received during the physical layer ranging window, wherein monitoring for a ranging response includes lengthening the physical layer ranging window at least until a ranging response is received during the physical layer ranging window, or (ii) until determining a ranging response is not within the transport layer ranging window.

11. The method of claim 1 wherein transmitting a ranging request and monitoring for a ranging response repeats (i) at least until a ranging response is received during the physical layer ranging window, wherein monitoring for a ranging response includes monitoring during a series of physical layer ranging windows within the transport layer ranging window, wherein the monitoring is enabled for an amount of time equal to each physical layer ranging window of the series and integration associated with the monitoring is reset at a beginning of each physical layer ranging window of the series, or (ii) until determining a response is not within the transport layer ranging window.

12. The method of claim 111 wherein monitoring during the series of physical layer ranging windows includes shifting the series within the transport layer ranging window (i) at least until a ranging response is received during at least one physical layer ranging window of the series, or (ii) until determining a ranging response is not within the transport layer ranging window.

13. The method of claim 11 wherein, in an event of receiving a ranging response in part during at least one physical layer ranging window, monitoring during the series of physical layer ranging windows includes shifting the series within the transport layer ranging window an amount expected to result in receiving a ranging response in full during one physical layer ranging window of the series during a later transport layer ranging window.

14. An apparatus for ranging an optical network terminal (ONT) in a passive optical network (PON), the apparatus comprising:
a transmitter to transmit a ranging request to an ONT in connection with a transport layer ranging window;
a monitor unit to monitor for a ranging response from the ONT during at least one physical layer ranging window within the transport layer ranging window, the transport layer ranging window having a duration longer than the physical layer ranging window; and
a determination unit to determine at least one metric associated with the ranging response for use in connection with upstream communications between the ONT and the OLT.

15. The apparatus of claim 14 further comprising a configuration unit to set at least one parameter, used in connection with upstream communications between the ONT and the OLT, based on the at least one metric associated with the ranging response.

16. The apparatus of claim 14 wherein the monitor unit includes a control unit operatively coupled to an Optical Line Terminal (OLT) receiver, the OLT receiver being controlled by the control unit.

17. The apparatus of claim 16 wherein the control unit enables the OLT receiver for an amount of time equal to the physical layer ranging window.

18. The apparatus of claim 17 wherein the control unit resets the OLT receiver at a beginning of the physical layer ranging window.

19. The apparatus of claim 16 wherein the monitor unit includes a measurement unit to measure a no-input signal metric on an upstream communications path received by the OLT receiver during the physical layer ranging window and the control unit responds to the measurement unit by reducing the physical layer ranging window if the measured no-input signal metric on the upstream communications path exceeds a threshold, and wherein the transmitter repeats transmitting a ranging request, the monitor unit repeats monitoring for a ranging response, and the control unit repeats reducing the physical layer ranging window at least until the measured no-input signal metric is less than the threshold.

20. The apparatus of claim 16 wherein the control unit dynamically adjusts the physical layer ranging window in an iterative manner (i) at least until the OLT receiver receives a ranging response during the physical layer ranging window, or (ii) until the control unit determines a ranging response is not within the transport layer ranging window.

21. The apparatus of claim 16 wherein the transmitter repeats transmitting a ranging request, the monitor unit repeats monitoring for a ranging response, and the control unit shifts the physical layer ranging window within the transport layer ranging window (i) at least until the OLT receiver receives a ranging response during the physical layer ranging window, or (ii) until the control unit determines a ranging response is not within the transport layer ranging window.

22. The apparatus of claim 20 wherein the control unit shifts the physical layer ranging window incrementally across the transport layer ranging window (i) at least until the OLT receiver receives a ranging response during the physical layer ranging window, or (ii) until the control unit determines a ranging response is not within the transport layer window.

23. The apparatus of claim 20 wherein, in an event the OLT receiver receives a ranging response in part during the physical layer ranging window, the control unit shifts the physical layer ranging window by an amount expected to result in the OLT receiver receiving a ranging response in full during the physical layer ranging window during a later transport layer ranging window.

24. The apparatus of claim 15 wherein the transmitter repeats transmitting a ranging request, the monitor unit repeats monitoring for a ranging response, and the control unit lengthens the physical layer ranging window (i) at least until the OLT receiver receives a ranging response during the physical layer ranging window, or (ii) until the control unit determines a ranging response is not within the transport layer window.

25. The apparatus of claim 15 wherein, during a series of physical layer ranging windows, the control unit enables the OLT receiver for an amount of time equal to each physical layer ranging window of the series and resets the OLT receiver at a beginning of each physical layer ranging window of the series.

26. The apparatus of claim 25 wherein the control unit shifts the series of physical layer ranging windows within the transport layer ranging window (i) at least until a ranging response is received during at least one physical layer ranging window of the series, or (ii) until the control unit determines a ranging response is not within the transport layer window.

27. The apparatus of claim 25 wherein, in an event of the OLT receiver receives a ranging response in part during at least one physical layer ranging window, the control unit shifts the series of physical layer ranging windows an amount expected to result in the OLT receiver receiving a ranging response in full during one physical layer ranging window of the series during a later transport layer ranging window.

28. An apparatus for ranging an Optical Network Terminal (ONT) in a Passive Optical Network (PON), the apparatus comprising:
means for transmitting a ranging request to an ONT in connection with a transport layer ranging window;
means for monitoring for a ranging response from the ONT during at least one physical layer ranging window within the transport layer ranging window, the transport layer ranging window having a duration longer than the physical layer ranging window; and
means for determining at least one metric associated with a ranging response for use in connection with upstream communications between the ONT and the OLT.
